(19) United States
(12) Patent Application Publication
(10) Pub. No.: US 2024/0063347 A1
(43) Pub. Date: Feb. 22, 2024

(54) DISPLAY APPARATUS

(71) Applicant: Samsung Display Co., Ltd., Yongin-si (KR)

(72) Inventors: Donggyu Baeck, Yongin-si (KR); Minseok Kim, Yongin-si (KR); Songyi Kim, Yongin-si (KR); Sujin Kim, Yongin-si (KR); Kiheon Lee, Yongin-si (KR); Myungjin Lee, Yongin-si (KR); Hyeokjin Lee, Yongin-si (KR); Hoyeon Ji, Yongin-si (KR); Yongseok Choi, Yongin-si (KR)

(73) Assignee: Samsung Display Co., Ltd., Yongin-si (KR)

(21) Appl. No.: 18/312,192

(22) Filed: May 4, 2023

(30) Foreign Application Priority Data
Aug. 19, 2022 (KR) 10-2022-0104276

(51) Int. Cl. H01L 33/50; H01L 25/075; H01L 33/54

(52) U.S. Cl. CPC H01L 33/505; H01L 33/504; H01L 25/0753; H01L 33/54

(57) ABSTRACT

Embodiments provide a display apparatus that includes a first substrate, a first light-emitting diode, a second light-emitting diode, and a third light-emitting diode, an encapsulation layer covering the first light-emitting diode, the second light-emitting diode, and the third light-emitting diode, a bank layer on the encapsulation layer, the bank layer including a first bank opening corresponding to the first light-emitting diode, a second bank opening corresponding to the second light-emitting diode, and a third bank opening corresponding to the third light-emitting diode, a first quantum dot layer disposed in the first bank, a second quantum dot layer disposed in the second bank opening, a first organic capping layer disposed in the second bank opening and covering the second quantum dot layer, and an inorganic capping layer covering the bank layer, the first quantum dot layer, and the second quantum dot layer.

### CROSS-REFERENCE TO RELATED APPLICATION(S)

This application claims priority to and benefits of Korean Patent Application No. 10-2022-0104276 under 35 U.S.C. § 119, filed on Aug. 19, 2022, in the Korean Intellectual Property Office, the entire contents of which are incorporated herein by reference.

### BACKGROUND

### 1. Technical Field

Embodiments relate to a display apparatus on which a high-quality image may be displayed.

### 2. Description of the Related Art

In general, a display apparatus includes pixels. For a full-color display apparatus, the pixels may emit light of different colors. To this end, at least some of the pixels of the display apparatus includes a color conversion unit. Accordingly, light of a first color generated by an emission unit of a pixel is converted into light of a second color by passing through a corresponding color conversion unit, and is emitted to the outside.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

In a display apparatus of the related art, when a color conversion unit is exposed to light and/or oxygen during a display manufacturing process, light conversion efficiency may decrease.

Embodiments include a display apparatus on which a high-quality image may be displayed. However, the embodiments are only examples, and the scope of the disclosure is not limited thereto.

Additional aspects will be set forth in part in the description that follows and, in part, will be apparent from the description, or may be learned by practice of the embodiments of the disclosure.

According to embodiments, a display apparatus may include a first substrate; a first light-emitting diode, a second light-emitting diode, and a third light-emitting diode, which are disposed on the first substrate and emit light of a wavelength belonging to a first wavelength band; an encapsulation layer covering the first light-emitting diode, the second light-emitting diode and the third light-emitting diode; a bank layer on the encapsulation layer, the bank layer including a first bank opening corresponding to the first light-emitting diode, a second bank opening corresponding to the second light-emitting diode, and a third bank opening corresponding to the third light-emitting diode; a first quantum dot layer disposed in the first bank opening and which converts light of a wavelength belonging to the first wavelength band to light of a wavelength belonging to a second wavelength band; a second quantum dot layer disposed in the second bank opening and which converts light of a wavelength belonging to the first wavelength band to light of a wavelength belonging to a third wavelength band; a first organic capping layer disposed in the second bank opening and covering the second quantum dot layer; and an inorganic capping layer covering the bank layer, the first quantum dot layer, and the first organic capping layer.

In an embodiment, the bank layer may further include a first bank layer on the encapsulation layer and having a lyophilic surface, and a second bank layer on the first bank layer and having a lyophobic surface.

In an embodiment, a fixed point at which an upper surface of the first organic capping layer contacts a sidewall of the second bank opening may coincide with or may be adjacent to a point at which an interface between the first bank layer and the second bank layer contacts the sidewall of the second bank opening.

In an embodiment, the second quantum dot layer may have a concave shape in which a thickness of a central portion is less than a thickness of a peripheral portion adjacent to a sidewall of the second bank opening.

In an embodiment, in the first organic capping layer, a thickness of a central portion may be equal to a thickness of a peripheral portion adjacent to the sidewall of the second bank opening.

In an embodiment, the first organic capping layer may have a convex shape in which a thickness of a central portion is greater than a thickness of a peripheral portion adjacent to the sidewall of the second bank opening.

In an embodiment, the second quantum dot layer may have a convex shape in which a thickness of a central portion is greater than a thickness of a peripheral portion adjacent to a sidewall of the second bank opening, and in the first organic capping layer, a thickness of a central portion may be equal to a thickness of a peripheral portion.

In an embodiment, a thickness of the first organic capping layer may be in a range of about 0.1 μm to about 3 μm.

In an embodiment, the second quantum dot layer may include InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or any mixture thereof.

In an embodiment, the first wavelength band may be in a range of about 450 nm to about 495 nm, and the third wavelength band may be in a range of about 495 nm to about 570 nm.

In an embodiment, the display apparatus may further include a second organic capping layer disposed in the first bank opening and covering the first quantum dot layer.

In an embodiment, the display apparatus may further include a second substrate over the first substrate with the bank layer therebetween, and a color filter layer disposed on a lower surface of the second substrate in a direction toward the first substrate, wherein the color filter layer may include a first filter opening, a second filter opening, and a third filter opening, which respectively overlap the first light-emitting diode, the second light-emitting diode, and the third light-emitting diode, when viewed from a direction perpendicular to the first substrate.

In an embodiment, the display apparatus may further include a low-refractive index layer contacting a lower surface of the color filter layer in the direction toward the first substrate.

In an embodiment, the display apparatus may further include a filler between the inorganic capping layer and the low-refractive index layer.

According to embodiments, a display apparatus may include a second substrate; a color filter layer on the second substrate and including a first filter opening, a second filter opening, and a third filter opening; a low-refractive index layer on the color filter layer; a bank layer on the low-refractive index layer, the bank layer including a first bank opening corresponding to the first filter opening, a second bank opening corresponding to the second filter opening, and a third bank opening corresponding to the third filter opening; a first quantum dot layer disposed in the first bank opening and which converts light of a wavelength belonging to a first wavelength band into light of a wavelength belonging to a second wavelength band; a second quantum dot layer disposed in the second bank opening and which converts light of a wavelength belonging to the first wavelength band to light of a wavelength belonging to a third wavelength band; a first organic capping layer disposed in the second bank opening and covering the second quantum dot layer; and an inorganic capping layer covering the bank layer, the first quantum dot layer, and the first organic capping layer.

In an embodiment, the bank layer may further include a first bank layer on the low-refractive index layer and having a lyophilic surface, and a second bank layer on the first bank layer and having a lyophobic surface.

In an embodiment, a fixed point at which an upper surface of the first organic capping layer contacts a sidewall of the second bank opening may coincide with or may be adjacent to a point at which an interface between the first bank layer and the second bank layer contacts the sidewall of the second bank opening.

In an embodiment, the second quantum dot layer may have a concave shape in which a thickness of a central portion is less than a thickness of a peripheral portion adjacent to a sidewall of the second bank opening.

In an embodiment, in the first organic capping layer, a thickness of a central portion may be equal to a thickness of a peripheral portion adjacent to the sidewall of the second bank opening.

In an embodiment, the first organic capping layer may have a convex shape in which a thickness of a central portion is greater than a thickness of a peripheral portion adjacent to the sidewall of the second bank opening.

In an embodiment, the second quantum dot layer may have a convex shape in which a thickness of a central portion is greater than a thickness of a peripheral portion adjacent to a sidewall of the second bank opening, and in the first organic capping layer, a thickness of a central portion may be equal to a thickness of a peripheral portion.

In an embodiment, the display apparatus may further include a second organic capping layer disposed in the first bank opening and covering the first quantum dot layer.

In an embodiment, the second quantum dot layer may include InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or any mixture thereof.

In an embodiment, the display apparatus may further include a first substrate under the second substrate with the bank layer therebetween; a first light-emitting diode, a second light-emitting diode, and a third light-emitting diode, which are disposed on the first substrate and emit light of a wavelength belonging to the first wavelength band; and an encapsulation layer covering the first light-emitting diode, the second light-emitting diode and the third light-emitting diode.

In an embodiment, the display apparatus may further include a filler between the encapsulation layer and the inorganic capping layer.

According to embodiments, a display apparatus may include a first substrate; a first light-emitting diode, a second light-emitting diode, and a third light-emitting diode, which are disposed on the first substrate and emit light of a wavelength belonging to a first wavelength band; an encapsulation layer covering the first light-emitting diode, the second light-emitting diode, and the third light-emitting diode; a bank layer on the encapsulation layer, the bank layer including a first bank opening corresponding to the first light-emitting diode, a second bank opening corresponding to the second light-emitting diode, and a third bank opening corresponding to the third light-emitting diode; a first quantum dot layer disposed in the first bank opening and which converts light of a wavelength belonging to the first wavelength band to light of a wavelength belonging to a second wavelength band; a second quantum dot layer disposed in the second bank opening and which converts light of a wavelength belonging to the first wavelength band to light of a wavelength belonging to a third wavelength band; a first organic capping layer disposed in the second bank opening and covering the second quantum dot layer; an inorganic capping layer covering the bank layer, the first quantum dot layer, and the first organic capping layer; an organic low-refractive index layer on the inorganic capping layer and filling the first bank opening, the second bank opening, and the third bank opening; an inorganic protective layer on the inorganic low-refractive index layer; and a color filter layer directly contacting the inorganic protective layer, wherein the color filter layer may include a first filter opening, a second filter opening, and a third filter opening, which respectively overlap the first light-emitting diode, the second light-emitting diode, and the third light-emitting diode, when viewed from a direction perpendicular to the first substrate.

These and/or other aspects will become apparent and more readily appreciated from the accompanying drawings, the claims, and the detailed description of the disclosure.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects and features of the disclosure will be more apparent by describing in detail embodiments thereof with reference to the accompanying drawings, in which:

FIG. 1 is a schematic perspective view of a display apparatus according to an embodiment;

FIG. 2 is a schematic cross-sectional view illustrating each sub-pixel of the display apparatus according to an embodiment;

FIG. 3 is a schematic diagram of a color conversion-transmissive layer of FIG. 2,

FIG. 4 is an equivalent circuit diagram illustrating a light-emitting diode and a sub-pixel circuit electrically connected to the light-emitting diode, included in the display apparatus according to an embodiment;

FIG. 5 is a schematic cross-sectional view illustrating the display apparatus, taken along line I-I′ in FIG. 1;

FIG. 6 is an enlarged schematic cross-sectional view illustrating region II of the display apparatus shown in FIG. 5;

FIGS. 7A and 7B are each a schematic cross-sectional view of a part of the display apparatus according to an embodiment;

FIG. 8 is a schematic cross-sectional view of a part of the display apparatus according to an embodiment;

FIGS. 9A to 9F are schematic cross-sectional views sequentially illustrating some operations of a method of manufacturing the display apparatus, according to an embodiment;

FIG. 10 is a schematic cross-sectional view of a part of the display apparatus according to an embodiment;

FIG. 11 is an enlarged schematic cross-sectional view of region III of the display apparatus shown in FIG. 10;

FIGS. 12A and 12B are each a schematic cross-sectional view of a part of the display apparatus according to an embodiment;

FIGS. 13A to 13F are schematic cross-sectional views sequentially illustrating some operations of a method of manufacturing the display apparatus, according to an embodiment;

FIG. 14 is a graph showing a light absorption efficiency increase rate and a light conversion efficiency increase rate according to a thickness of a quantum dot layer of the display apparatus according to an embodiment;

FIG. 15 is a graph showing light conversion efficiency according to a light exposure time of the display apparatus according to an embodiment and a comparative example;

FIG. 16 is a graph showing light conversion efficiency according to a light exposure time of the display apparatus according to an embodiment and comparative examples; and

FIG. 17 is a schematic cross-sectional view of a part of the display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

In the specification, the terms “x-axis”, “y-axis”, and “z-axis” are not limited to three axes in an orthogonal coordinate system (e.g., a Cartesian coordinate system), and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

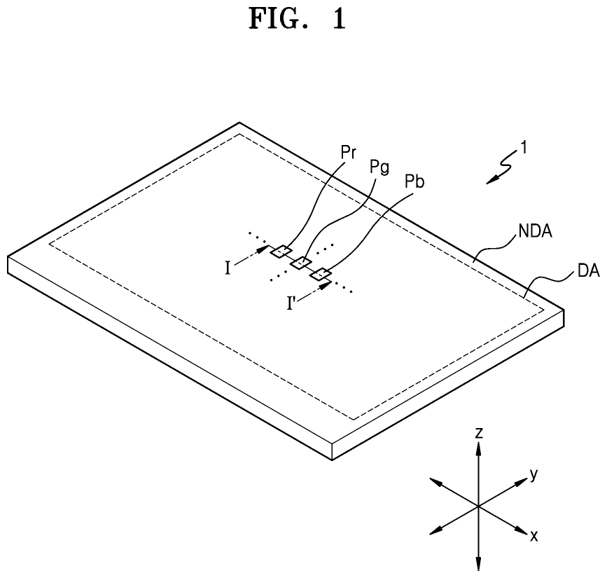

FIG. 1 is a schematic perspective view of a display apparatus 1 according to an embodiment.

Referring to FIG. 1, the display apparatus 1 may include a display area DA and a non-display area NDA outside the display area DA. The display apparatus 1 may provide an image through a two-dimensional array of sub-pixels arranged on an x-y plane. The sub-pixels may include a first sub-pixel, a second sub-pixel, and a third sub-pixel, and hereinafter, for convenience of explanation, a case in which the first sub-pixel is a red sub-pixel Pr, the second sub-pixel is a green sub-pixel Pg, and the third sub-pixel is a blue sub-pixel Pb is described.

The red sub-pixel Pr, the green sub-pixel Pg, and the blue sub-pixel Pb are areas in which red, green, and blue light may be respectively emitted, and the display apparatus 1 may provide an image by using light emitted from the sub-pixels.

Each of the red sub-pixel Pr, the green sub-pixel Pg, and the blue sub-pixel Pb may have a polygonal shape when viewed from a direction (e.g., a z-axis direction) perpendicular to an upper surface of the display apparatus 1. In FIG. 1, each of the red sub-pixel Pr, the green sub-pixel Pg, and the blue sub-pixel Pb has a quadrilateral shape when viewed from the direction (e.g., a z-axis direction) perpendicular to the upper surface of the display apparatus 1. However, the disclosure is not limited thereto. For example, each of the red sub-pixel Pr, the green sub-pixel Pg, and the blue sub-pixel Pb may have a circular or an elliptical shape when viewed from the direction (e.g., a z-axis direction) perpendicular to the upper surface of the display apparatus 1. A shape of each of the red sub-pixel Pr, the green sub-pixel Pg, and the blue sub-pixel Pb when viewed from the direction (e.g., a z-axis direction) perpendicular to the upper surface of the display apparatus 1 may be defined by a first color filter layer 810, a second color filter layer 820, and/or a third color filter layer 830, which will be described below.

The non-display area NDA, in which no image is provided, may entirely surround the display area DA. In the non-display area NDA, a driver or a main voltage line, which are configured to provide electrical signals or power to sub-pixel circuits, may be arranged. The non-display area NDA may include a pad, which is an area to which an electronic element or a printed circuit board may be electrically connected.

The display area DA may have a polygonal shape, including a quadrangle, as shown in FIG. 1. For example, the display area DA may have a rectangular shape having a horizontal length greater than a vertical length, a rectangular shape having a horizontal length less than a vertical length, or a square shape. In other embodiments, the display area DA may have various shapes, such as an ellipse or a circle.

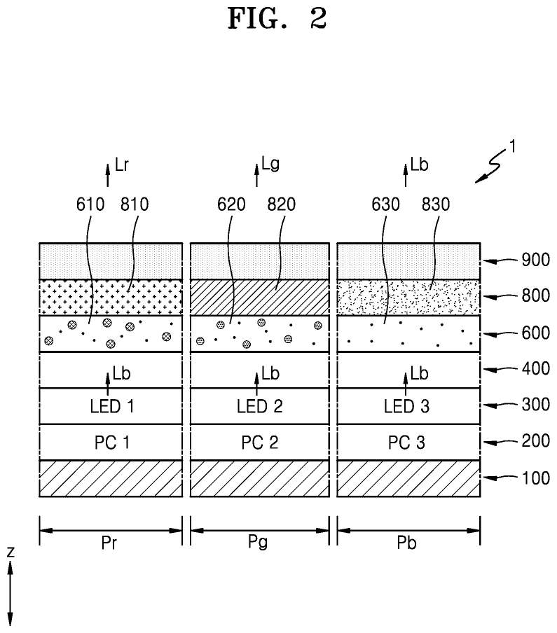

FIG. 2 is a schematic cross-sectional view illustrating each sub-pixel of the display apparatus 1 according to an embodiment.

Referring to FIG. 2, the display apparatus 1 may include a circuit layer 200 on a first substrate 100. The circuit layer 200 may include first to third sub-pixel circuits PC1, PC2, and PC3, and the first to third sub-pixel circuits PC1, PC2, and PC3 may be electrically connected to first to third light-emitting diodes LED1, LED2, and LED3 of a light-emitting diode layer 300, respectively.

Each of the first to third light-emitting diodes LED1, LED2, and LED3 may be an organic light-emitting diode including an organic material. In another embodiment, each of the first to third light-emitting diodes LED1, LED2, and LED3 may be an inorganic light-emitting diode including an inorganic material. The inorganic light-emitting diode may include a PN junction diode including inorganic semiconductor-based materials. When a voltage is applied to the PN junction diode in a forward direction, holes and electrons may be injected thereinto, and energy generated by recombination of the holes and the electrons may be converted into light energy to emit light of a certain color. The inorganic light-emitting diode described above may have a width of several to several hundred micrometers or several to several hundred nanometers. In embodiments, each of the first to third light-emitting diodes LED1, LED2, and LED3 may be a light-emitting diode including quantum dots. As described above, an emission layer of each of the first to third light-emitting diodes LED1, LED2, and LED3 may include an organic material, an inorganic material, quantum dots, an organic material with quantum dots, or an inorganic material with quantum dots.

The first to third light-emitting diodes LED1, LED2, and LED3 may emit light of a same color. For example, light (e.g., blue light Lb) emitted by the first to third light-emitting diodes LED1, LED2, and LED3 may pass through a color conversion-transmissive layer 600 and an encapsulation layer 400 on the light-emitting diode layer 300.

The color conversion-transmissive layer 600 may include optical units that transmit light (e.g., blue light Lb) emitted from the light-emitting diode layer 300 with or without color conversion. For example, the color conversion-transmissive layer 600 may include color conversion units and a transmissive unit, wherein the color conversion units convert light (e.g., blue light Lb) emitted from the light-emitting diode layer 300 into light of another color, and the transmissive unit transmits light (e.g., blue light Lb) emitted from the light-emitting diode layer 300 without color conversion. The color conversion-transmissive layer 600 may include a first quantum dot layer 610 corresponding to the red sub-pixel Pr, a second quantum dot layer 620 corresponding to the green sub-pixel Pg, and a transmissive layer 630 corresponding to the blue sub-pixel Pb. The first quantum dot layer 610 may convert the blue light Lb into red light Lr, and the second quantum dot layer 620 may convert the blue light Lb into green light Lg. The transmissive layer 630 may transmit the blue light Lb without conversion.

The blue light Lb emitted from the light-emitting diode layer 300 may be light of a wavelength belonging to a first wavelength band. For example, the first wavelength band may be in a range of about 450 nm to about 495 nm. The red light Lr into which the blue light Lb is converted by the first quantum dot layer 610 may be light of a wavelength belonging to a second wavelength band. For example, the second wavelength band may be in a range of about 625 nm to about 780 nm. The green light Lg into which the blue light Lb is converted by the second quantum dot layer 620 may be light of a wavelength belonging to a third wavelength band. For example, the third wavelength band may be in a range of about 495 nm to about 570 nm. However, the disclosure is not limited thereto, and a wavelength band to which a wavelength of light emitted from the light-emitting diode layer 300 belongs and a wavelength band to which a wavelength of the light after conversion belongs may be modified.

A color filter layer 800 may be disposed on the color conversion-transmissive layer 600. The color filter layer 800 may include the first to third color filter layers 810, 820, and 830, which are of different colors. For example, the first color filter layer 810 may be a red color filter, the second color filter layer 820 may be a green color filter, and the third color filter layer 830 may be a blue color filter.

Each of the light color-converted by the color conversion-transmissive layer 600 and the light transmitted by the color conversion-transmissive layer 600 may have improved color purity by passing through the first to third color filter layers 810, 820, and 830. The color filter layer 800 may prevent, or minimize, reflection and recognition of external light (e.g., light incident toward the display apparatus 1 from the outside of the display apparatus 1) by a user.

A transmissive base layer may be included on the color filter layer 800. In an embodiment, the transmissive base layer, which is a second substrate 900, may be integrated such that the color conversion-transmissive layer 600 and the encapsulation layer 400 face each other after the color filter layer 800 and the color conversion-transmissive layer 600 are formed on the second substrate 800. In another embodiment, the color conversion-transmissive layer 600 may be integrated such that the color filter layer 800 and the color conversion-transmissive layer 600 face each other after forming the color conversion-transmissive layer 600 on the encapsulation layer 400 and forming the color filter layer 800 on the second substrate 900.

The second substrate 900 may include glass or a transmissive organic material. For example, the second substrate 900 may include a transmissive organic material, such as acryl-based resin. In some embodiments, another optical film, e.g., an anti-reflection (AR) film or the like, may be disposed on the second substrate 900.

The display apparatus 1 having the structure described above may include electronic devices capable of displaying a moving image or a still image, such as televisions, advertisement boards, cinema screens, monitors, tablet personal computers (PC), and laptops.

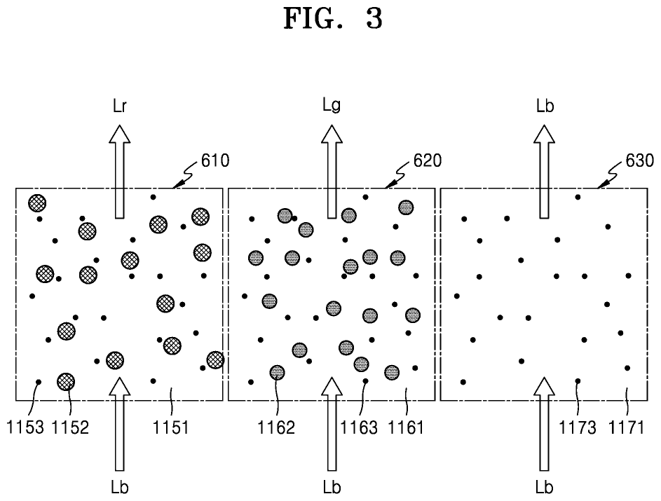

FIG. 3 is a schematic diagram illustrating each optical unit of the color conversion-transmissive layer of FIG. 2.

Referring to FIG. 3, the first quantum dot layer 610 may convert blue light Lb incident thereon into red light Lr. As shown in FIG. 3, the first quantum dot layer 610 may include a first photosensitive polymer 1151 and first quantum dots 1152 and first scattering particles 1153 dispersed in the first photosensitive polymer 1151.

The first quantum dots 1152 may be excited by the blue light Lb and may isotropically emit the red light Lr, which has a longer wavelength than the blue light Lb. The first photosensitive polymer 1151 may be an organic material having light transmission properties. The first scattering particles 1153 may scatter the blue light Lb that is not absorbed by the first scattering particles 1153 to excite more first quantum dots 1152, thereby improving color conversion efficiency. The first scattering particles 1153 may scatter incident light in multiple directions regardless of an incident angle, without substantially converting a wavelength of the light. Accordingly, the first scattering particles 1153 may improve side visibility of the display apparatus. For example, the first scattering particles 1153 may be titanium oxide (TiO₂) or metal particles. The first quantum dots 1152 may be selected from among Group II-VI semiconductor compounds, Group III-V semiconductor compounds, Group III-VI semiconductor compounds, Group I-III-VI semiconductor compounds, Group IV-VI semiconductor compounds, or any combinations thereof.

Examples of Group II-VI semiconductor compounds may include: a binary compound, such as CdS, CdSe, CdTe, ZnS, ZnSe, ZnTe, ZnO, HgS, HgSe, HgTe, MgSe, or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound, such as CnZnSeS, CdZnSeTe, CdZnSTe, CdHgSeS, CdHgSeTe, CdHgSTe, HgZnSeS, HgZnSeTe, or HgZnSTe; or any mixture thereof.

Examples of Group III-V semiconductor compounds may include: a binary compound, such as GaN, GaP, GaAs, GaSb, AlN, AlP, AlAs, AlSb, InN, InP, InAs, or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound, such as GaAlNAs, GaAlNSb, GaAlPAs, GaAlPSb, GaAlNP, GaInNP, GaInNAs, GaInNSb, GaInPAs, GaInPSb, InAlNP, InAlNAs, InAlNSb, InAlPAs, or InAlPSb; or any mixture thereof. Group III-V semiconductor compounds may further include a Group II element. Examples of Group III-V semiconductor compounds further including the Group II element may include InZnP, InGaZnP, or InAlZnP.

Examples of Group III-VI semiconductor compounds may include: a binary compound, such as GaS, GaSe, Ga₂Se₃, GaTe, InS, In₂S₃, InSe, In₂Se₃, or InTe; a ternary compound, such as AgInS, AgInS₂, CuInS, CuInS₂, InGaS₃, or InGaSe₃; or any combinations thereof.

Examples of Group I-III-VI semiconductor compounds may include: a ternary compound, such as AgInS, AgInS₂, CuInS, CuInS₂, CuGaO₂, AgGaO₂, or AgAlO₂; or any mixture thereof.

Examples of Group IV-VI semiconductor compounds may include: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, or SnPbTe; a quaternary compound, such as SnPbSSe, SnPbSeTe, or SnPbSTe; or any mixture thereof.

Examples of Group IV elements or compounds may include: a single-element material, such as Si or Ge; a binary compound, such as SiC or SiGe; or any mixture thereof.

Each element included in a multi-element compound, such as a binary compound, a ternary compound, and a quaternary compound, may be present in particles in a uniform concentration or in a non-uniform concentration.

A quantum dot may have a single structure or a core-shell structure, in which a concentration of each element included in the corresponding quantum dot is uniform. For example, in case that the quantum dot has a core-shell structure a material included in the core and a material included in the shell may be different from each other. The shell of the quantum dot may serve as a protective layer for maintaining semiconductor properties by preventing chemical denaturation of the core and/or may serve as a charging layer for imparting electrophoretic properties to the quantum dot. The shell may include a layer or layers. An interface between the core and the shell may have a concentration gradient in which the concentration of elements in the shell decreases toward the core.

Examples of the shell of the quantum dot may include a metal oxide, a non-metal oxide, a semiconductor compound, or any combinations thereof. Examples of the metal oxide or the non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound, such as MgAl₂O₄, CoFe₂O₄, NiFe₂O₄, or CoMn₂O₄; or any mixture thereof. Examples of the semiconductor compound may include Group II-VI semiconductor compounds, Group III-V semiconductor compounds, Group III-VI semiconductor compounds, Group I-III-VI semiconductor compounds, Group IV-VI semiconductor compounds, as described above, or any mixture thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any mixture thereof.

The quantum dot may have a full width of half maximum (FWHM) of an emission wavelength spectrum of less than or equal to about 45 nm, For example, the quantum dot may have an FWHM of the emission wavelength spectrum of less than or equal to about 40 nm. For another example, the quantum dot may have an FWHM of the emission wavelength spectrum of less than or equal to about 30 nm. Color purity or color reproducibility may be improved in this range. Light emitted from the quantum dots may be emitted in all directions, so that an optical viewing angle may be improved.

The quantum dots may be in the form of spherical, pyramidal, multi-arm or cubic, nanoparticles, nanowires, nanofibers, or nanoplatelet particles.

Because an energy bandgap may be adjusted by adjusting sizes of the quantum dots, light of various wavelength bands may be obtained from a quantum dot emission layer. Accordingly, by using quantum dots of different sizes, a light-emitting element emitting light of various wavelengths may be implemented. The sizes of the quantum dots may be selected such that red, green, and/or blue light may be emitted. The size of the quantum dots may be configured such that light of various colors combine with each other to emit white light.

The second quantum dot layer 620 may convert the blue light Lb incident thereon into the green light Lg. As shown in FIG. 3, the second quantum dot layer 620 may include a second photosensitive polymer 1161 and second quantum dots 1162 and second scattering particles 1163 dispersed in the second photosensitive polymer 1161.

The second quantum dots 1162 may be excited by the blue light Lb and may isotropically emit the green light Lg having a greater wavelength than the blue light Lb. The second photosensitive polymer 1161 may be an organic material having light transmission properties.

The second scattering particles 1163 may scatter the blue light Lb that is not absorbed by the second quantum dots 1162 to excite more second quantum dots 1162, thereby improving color conversion efficiency. For example, the second scattering particles 1163 may be TiO₂ or metal particles. The second quantum dots 1162 may be selected from among Group III-V compounds, Group III-VI compounds, Group II-VI compounds, Group I-III-VI compounds, or any mixture thereof. In an embodiment, the second quantum dots 1162 may include InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or any mixture thereof. Because a quantum confinement effect occurs in a size relatively greater than a general size of the quantum dots, the second quantum dots 1162 may reduce a quantization period in which the blue light Lb is not absorbed and thus have high light conversion efficiency.

In some embodiments, the first quantum dots 1152 may include a same material as a material of the second quantum dots 1162. Sizes of the first quantum dots 1152 may be greater than sizes of the second quantum dots 1162.

The transmissive layer 630 may transmit the blue light Lb without converting the blue light Lb incident to the transmissive layer 630. As shown in FIG. 3, the transmissive layer 630 may include a third photosensitive polymer 1171, in which third scattering particles 1173 are dispersed. The third photosensitive polymer 1171 may be an organic material having transmissivity, such as silicon resin and epoxy resin, and may include a same material as materials of the first and second photosensitive polymers 1151 and 1161. The third scattering particles 1173 may scatter and emit the blue light Lb, and may include a same material as materials of the first and second scattering particles 1153 and 1163.

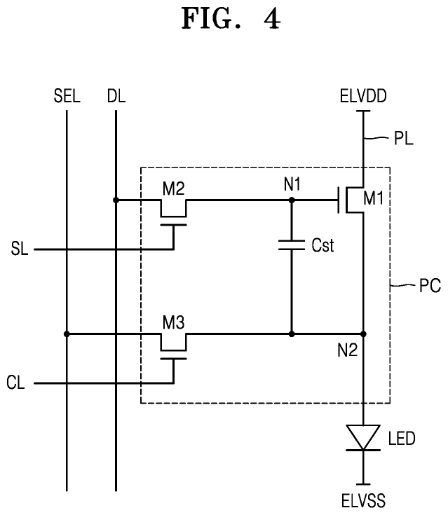

FIG. 4 is an equivalent circuit diagram illustrating a light-emitting diode LED and a sub-pixel circuit PC electrically connected to the light-emitting diode LED, included in the display apparatus according to an embodiment. The sub-pixel circuit PC shown in FIG. 4 may correspond to each of the first to third sub-pixel circuits PC1, PC2, and PC3 described above with reference to FIG. 2, and the light-emitting diode LED of FIG. 4 may correspond to each of the first to third light-emitting diodes LED1, LED2, and LED3 described above with reference to FIG. 2.

Referring to FIG. 4, the light-emitting diode LED, e.g., a pixel electrode (e.g., an anode) of the light-emitting diode LED, may be connected to the sub-pixel circuit PC, and an opposite electrode (e.g., a cathode) of the light-emitting diode LED may be electrically connected to a main common voltage line to be described later, and receive a common voltage ELVSS. The light-emitting diode LED may emit light of a luminance corresponding to an amount of current received from the sub-pixel circuit PC.

The sub-pixel circuit PC may control an amount of current flowing from a driving voltage ELVDD to the common voltage ELVSS via the light-emitting diode LED, in response to a data signal. The sub-pixel circuit PC may include a first transistor M1, a second transistor M2, a third transistor M3, and a storage capacitor Cst.

Each of the first transistor M1, the second transistor M2, and the third transistor M3 may be an oxide semiconductor transistor including a semiconductor layer formed of an oxide semiconductor, or may be a silicon semiconductor including a semiconductor layer formed of polysilicon. Depending on a type of a transistor, a first electrode of the transistor may be one of a source electrode and a drain electrode, and a second electrode of the transistor may be the other one of the source electrode and drain electrode.

The first electrode of the first transistor M1 may be connected to a driving voltage line PL configured to apply the driving voltage ELVDD, and the second electrode may be connected to the pixel electrode of the light-emitting diode LED. A gate electrode of the first transistor M1 may be connected to a first node N1. The first transistor M1 may control an amount of current flowing from the driving voltage ELVDD to the light-emitting diode LED, in response to a voltage of the first node N1.

The second transistor M2 may be a switching transistor. A first electrode of the second transistor M2 may be connected to a data line DL, and a second electrode may be connected to the first node N1. A gate electrode of the second transistor M2 may be connected to a scan line SL. The second transistor M2 may be turned on when a scan signal is received via the scan line SL and may electrically connect the data line DL to the first node N1.

The third transistor M3 may be an initialization transistor and/or a sensing transistor. A first electrode of the third transistor M3 may be connected to a second node N2, and a second electrode may be connected to a sensing line SEL. A gate electrode of the third transistor M3 may be connected to a control line CL.

The storage capacitor Cst may be connected between the first node N1 and the second node N2. For example, a first capacitor electrode of the storage capacitor Cst may be connected to the gate electrode of the first transistor M1, and a second capacitor electrode of the storage capacitor Cst may be connected to the pixel electrode of the light-emitting diode LED.

In FIG. 4, the first transistor M1, the second transistor M2, and the third transistor M3 are n-channel metal-oxide-semiconductor field-effect transistors (NMOS). However, the disclosure is not limited thereto. For example, at least one of the first transistor M1, the second transistor M2, and the third transistor M3 may be formed as a p-channel metal-oxide-semiconductor field-effect transistor (PMOS).

In FIG. 4, three transistors are shown. However, the disclosure is not limited thereto. The sub-pixel circuit PC may include four or more transistors.

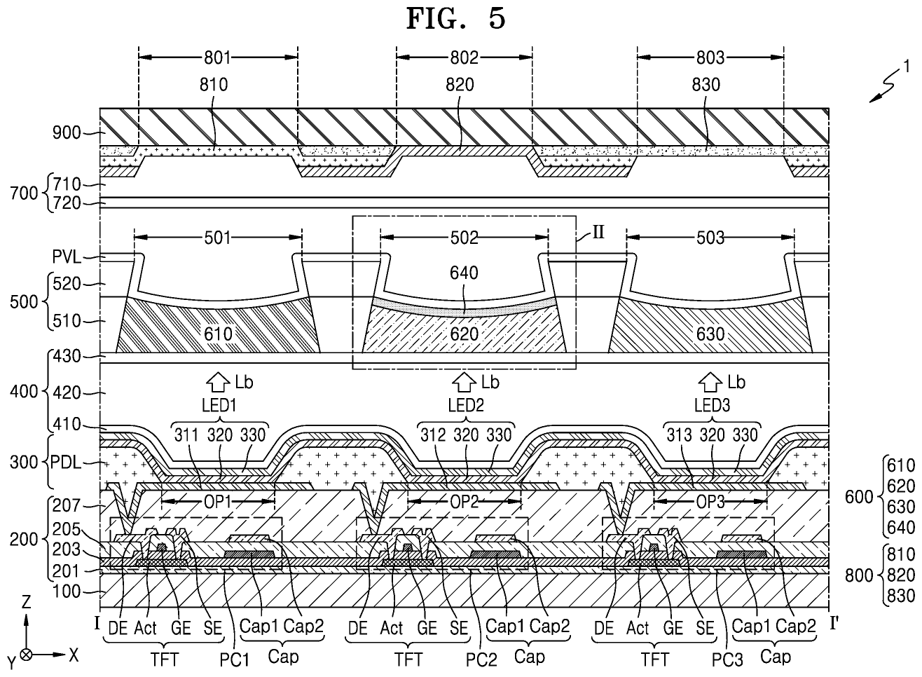

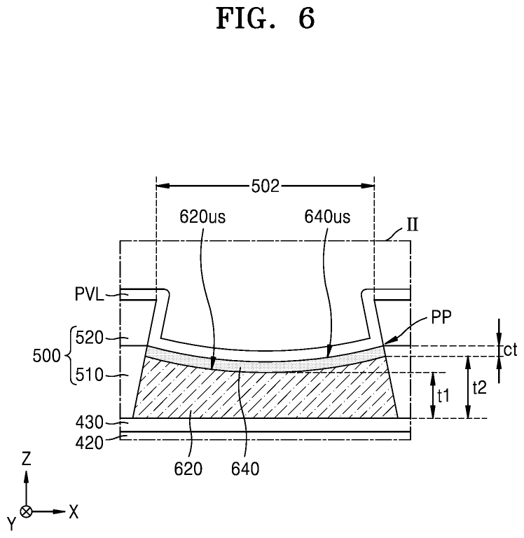

FIG. 5 is a schematic cross-sectional view illustrating the display apparatus, taken along line I-I′ in FIG. 1, and FIG. 6 is an enlarged schematic cross-sectional view illustrating region II of the display apparatus shown in FIG. 5.

Referring to FIG. 5, the circuit layer 200 may be disposed on a substrate 100, the light-emitting diode layer 300 including the first to third light-emitting diodes LED1, LED2, and LED3 may be disposed on the circuit layer 200, and the light-emitting diode layer 300 may be sealed by the encapsulation layer 400. A bank layer 500 including first to third bank openings 501, 502, and 503 respectively corresponding to the first to third light-emitting diodes LED1, LED2, and LED3 may be disposed on the encapsulation layer 400, and the color conversion-transmissive layer 600 including the first quantum dot layer 610, the second quantum dot layer 620, and the transmissive layer 630 may be disposed in the first to third bank openings 501, 502, and 503. The second substrate 900 may be located on the color conversion-transmissive layer 600. The color filter layer 800 including first to third filter openings 801, 802, and 803 respectively corresponding to the first to third light-emitting diodes LED1, LED2, and LED3 may be disposed on a lower surface of the second substrate 900 in a direction toward the first substrate 100 (e.g., a −z direction). A low-refractive index layer 700 may be arranged between the color filter layer 800 and the first quantum dot layer 610, the second quantum dot layer 620, and the transmissive layer 630.

The first substrate 100 may include glass, metal, or polymer resin. For example, the first substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the first substrate 100 may have a multi-layer structure including two layers and a barrier layer therebetween, wherein the two layers include the polymer resin described above, and the barrier layer includes an inorganic material (such as silicon oxide, silicon nitride, silicon oxynitride, or the like), and various modifications may be made.

A buffer layer 201 may be disposed on the first substrate 100. The buffer layer 201 may prevent impurities from permeating into a semiconductor layer Act of a thin-film transistor TFT from the first substrate 100. The buffer layer 201 may include an inorganic insulating material, such as silicon oxide, silicon nitride, and/or silicon oxynitride.

The circuit layer 200 including the first to third sub-pixel circuits PC1, PC2, and PC3 may be disposed on the buffer layer 201. Each of the first to third sub-pixel circuits PC1, PC2, and PC3 may include the thin-film transistor TFT and a capacitor Cap. The thin-film transistor TFT and the capacitor Cap shown in FIG. 5 may correspond to the first transistor M1 and the storage capacitor Cst shown in FIG. 4, respectively.

The semiconductor layer Act of the thin-film transistor TFT may be disposed on the buffer layer 201. The semiconductor layer Act may include an oxide semiconductor. The oxide semiconductor may include indium gallium zinc oxide (IGZO), zinc tin oxide (ZTO), indium zinc oxide (IZO), or the like. In another embodiment, the semiconductor layer Act may include polysilicon, amorphous silicon, or an organic semiconductor. The semiconductor layer Act may include a channel area and conductive areas at opposite sides of the channel area, wherein the channel area overlaps a gate electrode GE, and the conductive areas are doped with impurities or are conductively disposed. Any of the conductive areas may be a source area, and the other one may correspond to a drain area.

The gate electrode GE may include various conductive materials and may have various layered structures, such as an Mo layer and an Al layer. The gate electrode GE may have a layered structure of an Mo layer, an Al layer, and another Mo layer. In another embodiment, the gate electrode GE may include a TiNₓ layer, an Al layer, and/or a Ti layer.

A source electrode SE and a drain electrode DE may also include various conductive materials and may have various layered structures, such as a Ti layer, an Al layer, and/or a Cu layer. Each of the source electrode SE may have a layered structure of a Ti layer, an Al layer, and another Ti layer.

In FIG. 5, the thin-film transistor TFT includes both the source electrode SE and the drain electrode DE. However, the disclosure is not limited thereto. For example, a source area of the semiconductor layer Act of the thin-film transistor TFT may be integrally provided as a single body with a drain area of a semiconductor layer of another thin-film transistor, and the thin-film transistor TFT may not include the source electrode SE. The source electrode SE and/or the drain electrode DE may be part of a line.

To ensure insulation between the semiconductor layer Act and the gate electrode GE, a gate insulating layer 203 may include an inorganic material, such as silicon oxide, silicon nitride, and/or silicon oxynitride, may be located between the semiconductor layer Act and the gate electrode GE. Further, an interlayer insulating layer 205 may include an inorganic material, such as silicon oxide, silicon nitride, and/or silicon oxynitride, may be disposed on the gate electrode GE, and the source electrode SE and the drain electrode DE may be disposed on the interlayer insulating layer 205. An insulating layer including an inorganic material, as described above may be formed by chemical vapor deposition (CVD) or atomic layer deposition (ALD). This may also apply to embodiments to be described below and modifications thereof.

The capacitor Cap may include a first capacitor electrode Cap1 and a second capacitor electrode Cap2. The first capacitor electrode Cap1 may be located on the gate insulating layer 203, and the second capacitor electrode Cap2 may be located on the interlayer insulating layer 205.

The first capacitor electrode Cap1 may include various conductive materials, and may have various layered structures, such as an Mo layer and an Al layer. The first capacitor electrode Cap1 may have a layered structure of an Mo layer, an Al layer, and another Mo layer. In another embodiment, the first capacitor electrode Cap1 may include a TiNₓ layer, an Al layer, and/or a Ti layer.

The second capacitor electrode Cap2 may also include various conductive materials and may have various layered structures, for example, a Ti layer, an Al layer, and/or a Cu layer. The second capacitor electrode Cap2 may have a layered structure of a Ti layer, an Al layer, and another Ti layer.

A planarization layer 207 may be formed on the thin-film transistor TFT and the capacitor Cap. The planarization layer 207 may have an approximately flat surface so that first to third pixel electrodes 311, 312, and 313 or the like may be located on a flat surface. The planarization layer 207 may include an organic insulating material, such as acrylic, benzocyclobutene (BCB), polyimide, and/or hexamethyldisiloxane (HMDSO). In FIG. 5, the planarization layer 207 includes a single layer. However, the planarization layer 207 may include layers, and various modifications may be made.

A first light-emitting diode LED1 including a first pixel electrode 311, an opposite electrode 330, and an intermediate layer 320 may be located on the planarization layer 207, wherein the intermediate layer 320 is located between first pixel electrode 311 and the opposite electrode 330 and includes an emission layer. As shown in FIG. 5, the first pixel electrode 311 may contact any of the source electrode SE and the drain electrode DE of the thin-film transistor TFT via a contact hole defined in the planarization layer 207 or the like, and be electrically connected to the first sub-pixel circuit PC1. The first pixel electrode 311 may include a transmissive conductive layer including a transmissive conductive oxide, such as ITO, In₂O₃, and IZO, and a reflective layer including a metal, such as Al or Ag. For example, the first pixel electrode 311 may have a three-layer structure of an ITO layer, an Ag layer, and another ITO layer.

The second light-emitting diode LED2 may include a second pixel electrode 312, the opposite electrode 330, and the intermediate layer 320 located between the second pixel electrode 312 and the opposite electrode 330 and including an emission layer. Similarly, the third light-emitting diode LED3 may include a third pixel electrode 313, the opposite electrode 330, and the intermediate layer 320 located between the third pixel electrode 313 and the opposite electrode 330 and including an emission layer. The second pixel electrode 312 may contact any of the source electrode SE and the drain electrode DE of the thin-film transistor TFT via a contact hole defined in the planarization layer 207 or the like, and be electrically connected to the second sub-pixel circuit PC2. The third pixel electrode 313 may contact any of the source electrode SE and the drain electrode DE of the thin-film transistor TFT via a contact hole defined in the planarization layer 207 or the like, and be electrically connected to the third sub-pixel circuit PC3. Descriptions of the first pixel electrode 311 provided above are applicable to the second pixel electrode 312 and the third pixel electrode 313.

As described above, the intermediate layer 320 including the emission layer may be located not only on the first pixel electrode 311 of the first light-emitting diode LED1, but also on the second pixel electrode 312 of the second light-emitting diode LED2 and the third pixel electrode 313 of the third light-emitting diode LED3. The intermediate layer 320 described above may be provided as a single body across the first pixel electrode 311, the second pixel electrode 312, and the third pixel electrode 313. However, the intermediate layer 320 may be patterned and located on the first pixel electrode 311, the second pixel electrode 312, and the third pixel electrode 313. The intermediate layer 320 may include a hole injection layer, a hole transport layer, and/or an electron transport layer in addition to the emission layer, and the layers included in the intermediate layer 320 described above may be integrally provided as a single body over the first pixel electrode 311, the second pixel electrode 312, and the third pixel electrode 313. However, some of the layers included in the intermediate layer 320 may be patterned and located to correspond to the first pixel electrode 311, the second pixel electrode 312, and the third pixel electrode 313. The emission layer included in the intermediate layer 320 may emit light of a wavelength belonging to a first wavelength band. The first wavelength band may be, for example, in a range of about 450 nm to about 495 nm, and light emitted by the first to third light-emitting diodes LED1, LED2, and LED3 may be the blue light Lb.

However, the intermediate layer 320 may include multiple layers instead of a single layer. For example, the intermediate layer 320 may have a stacked structure of a first emission layer and a second emission layer with a charge generation layer located therebetween. The hole transport layer or the electron transport layer may be located between the first emission layer and the charge generation layer and between the second emission layer and the charge generation layer.

The opposite electrode 330 on the intermediate layer 320 may also be integrally provided as a single body across the first pixel electrode 311 to the third pixel electrode 313. The opposite electrode 330 may include a transmissive conductive layer including ITO, In₂O₃, or IZO, and may include a semi-transmissive layer including a metal, such as Al, Li, Mg, Yb, or Ag. For example, the opposite electrode 330 may be a semi-transmissive layer including MgAg, AgYb, Yb/MgAg, or Li/MgAg.

A pixel-defining layer PDL may be disposed on the planarization layer 207. The pixel-defining layer PDL may include pixel openings respectively corresponding to the first to third pixel electrodes 311, 312, and 313. For example, the pixel-defining layer PDL may include a first pixel opening OP1 exposing a central portion of the first pixel electrode 311, a second pixel opening OP2 exposing a central portion of the second pixel electrode 312, and a third pixel opening OP3 exposing a central portion of the third pixel electrode 313, the first pixel opening OP1 covering an edge of each of the first pixel electrode 311, the second pixel electrode 312, and the third pixel electrode 313. As shown in FIG. 5, the pixel-defining layer PDL may increase a distance between the opposite electrode 330 and an edge of each of the first pixel electrode 311, the second pixel electrode 312, and the third pixel electrode 313, thereby preventing an arc or the like from occurring at the edges of the first pixel electrode 311, the second pixel electrode 312, and the third pixel electrode 313. The pixel-defining layer PDL described above may include an organic material, such as polyimide or HMDSO.

Organic light-emitting elements including the first pixel electrode 311, the second pixel electrode 312, the third pixel electrode 313, the intermediate layer 320, which includes an emission layer, and the opposite electrode 330, may be readily deteriorated by moisture or oxygen. Accordingly, to protect the organic light-emitting elements from external moisture or oxygen, the display apparatus may include the encapsulation layer 400 covering the organic light-emitting elements.

The encapsulation layer 400 may include at least one inorganic encapsulation layer and at least one organic encapsulation layer. For example, the encapsulation layer 400 may include a first inorganic encapsulation layer 410, a second inorganic encapsulation layer 430, and an organic encapsulation layer 420 therebetween.

Each of the first inorganic encapsulation layer 410 and the second inorganic encapsulation layer 430 may include at least one inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂), and may be formed by CVD or the like. The organic encapsulation layer 420 may include a polymer-based material. The polymer-based material may include silicon-based resin, acryl-based resin (e.g., poly(methyl methacrylate), polyacrylic acid, etc.), epoxy-based resin, polyimide, and polyethylene.

The first inorganic encapsulation layer 410 formed by CVD has an approximately uniform thickness, and an upper surface of the first inorganic encapsulation layer 410 is not flat, as shown in FIG. 5. However, an upper surface of the organic encapsulation layer 420 may have an approximately flat shape, and accordingly, the second inorganic encapsulation layer 430 on the organic encapsulation layer 420 may also have an approximately flat shape.

The bank layer 500 including the first to third bank openings 501, 502, and 503 may be disposed on the encapsulation layer 400. The first to third bank openings 501, 502, and 503 of the bank layer 500 may correspond to the first to third light-emitting diodes LED1, LED2, and LED3, respectively. The first bank opening 501 of the bank layer 500 may correspond to the first pixel opening OP1 of the pixel-defining layer PDL exposing the first pixel electrode 311, the second bank opening 502 may correspond to the second pixel opening OP2 of the pixel-defining layer PDL exposing the second pixel electrode 312, and the third bank opening 503 may correspond to the third pixel opening OP3 of the pixel-defining layer PDL exposing the third pixel electrode 313.

For example, when viewed from a direction (e.g., a z-axis direction) perpendicular to the first substrate 100, the first bank opening 501 of the bank layer 500 may overlap the first pixel opening OP1 of the pixel-defining layer PDL exposing the first pixel electrode 311, the second bank opening 502 may overlap the second pixel opening OP2 of the pixel-defining layer PDL exposing the second pixel electrode 312, and the third bank opening 503 may overlap the third pixel opening OP3 of the pixel-defining layer PDL exposing the third pixel electrode 313. Similarly, the first bank opening 501 of the bank layer 500 may correspond to the first pixel electrode 311, the second bank opening 502 of the bank layer 500 may correspond to the second pixel electrode 312, and the third bank opening 503 of the bank layer 500 may correspond to the third pixel electrode 313.

In an embodiment, an area of the first bank opening 501 of the bank layer 500 may be greater than an area of the first pixel opening OP1 of the pixel-defining layer PDL, an area of the second bank opening 502 may be greater than an area of the second pixel opening OP2, and an area of the third bank opening 503 may be greater than an area of the third pixel opening OP3. Accordingly, light generated on the first pixel opening OP1 of the pixel-defining layer PDL may be sufficiently incident into the first bank opening 501 of the bank layer 500, light generated on the second pixel opening OP2 of the pixel-defining layer PDL may be sufficiently incident into the second bank opening 502 of the bank layer 500, and light generated on the third pixel opening OP3 of the pixel-defining layer PDL may be sufficiently incident into the third bank opening 503 of the bank layer 500.

The bank layer 500 may include various materials, for example, an organic material, such as BCB or HMDSO. When necessary, the bank layer 500 may include a photoresist material, and through this, the bank layer 500 may be readily formed through a process, such as exposure and development. Because the bank layer 500 is formed on the first substrate 100 through a process, such as exposure and development, it may be shown such that the bank layer 500 has a reverse-tapered shape with reference to the first substrate 100. For example, an area of a surface of the bank layer 500 in a direction toward the first substrate 100 may be less than an area of a surface of the bank layer 500 in a direction toward the second substrate 900.

In an embodiment, as shown in FIG. 5, the bank layer 500 may include a first bank layer 510 having a lyophilic surface and a second bank layer 520 having a lyophobic surface. For example, the first bank layer 510 including a lyophilic material may be located on the encapsulation layer 400, and the second bank layer 520 including a lyophobic surface may be located on the first bank layer 510. In another embodiment, the first bank layer 510 and the second bank layer 520 may include a same material as each other, and lyophobic properties may be rendered only to the surface of the second bank layer 520 by using CF₄ plasma treatment or the like.

The blue light Lb generated by the first light-emitting diode LED1 may be converted into the red light Lr by the first quantum dot layer 610 located in the first bank opening 501, and emitted to the outside. The first quantum dot layer 610 described above may overlap the first pixel electrode 311 when viewed from the direction (e.g., a z-axis direction) perpendicular to the first substrate 100. The first quantum dot layer 610 may include a photosensitive polymer, quantum dots, and scattering particles, which have light-transmitting properties.

As described above, quantum dots of the first quantum dot layer 610 may include a material selected from among Group II-VI semiconductor compounds, Group III-V semiconductor compounds, Group III-VI semiconductor compounds, Group I-III-VI semiconductor compounds, Group IV-VI semiconductor compounds, or any mixture thereof. A diameter of such a quantum dot may be, for example, in a range of about 1 nm to about 10 nm.

The blue light Lb generated by the second light-emitting diode LED2 may be converted into the green light Lg by the second quantum dot layer 620 located in the second bank opening 502, and emitted to the outside. The second quantum dot layer 620 described above may overlap the second pixel electrode 312 when viewed from the direction (e.g., a z-axis direction) perpendicular to the first substrate 100. The second quantum dot layer 620 may include a photosensitive polymer, quantum dots, and scattering particles, which have light-transmitting properties.

As described above, quantum dots of the second quantum dot layer 620 may include a material selected from among Group III-V compounds, Group III-VI compounds, Group II-VI compounds, Group I-III-VI compounds, and a mixture thereof. In an embodiment, the second quantum dot layer 620 may include InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or any mixture thereof.

A first organic capping layer 640 may be located on the second quantum dot layer 620 in the second bank opening 502. The first organic capping layer 640 described above may overlap the second pixel electrode 312 when viewed from the direction (e.g., a z-axis direction) perpendicular to the first substrate 100.

The first organic capping layer 640 may be a photosensitive polymer. For example, a monomer for forming the first organic capping layer 640 may be photosensitive acryl-based resin. In an embodiment, the monomer for forming the first organic capping layer 640 may include hexamethylene diacrylate, tetraethylene glycol diacrylate, dipropylene glycol diacrylate, tripropylene glycol diacrylate, or any mixture thereof.

As shown in FIG. 6, the second quantum dot layer 620 may have a concave shape in which a thickness t1 of a central portion is less than a thickness t2 of a peripheral portion adjacent to a sidewall of the second bank opening 502. The first organic capping layer 640 may have a constant thickness ct on an upper surface 620us of the second quantum dot layer 620. For example, an upper surface 640us of the first organic capping layer 640 may have a same or similar shape as or to the upper surface 620us of the second quantum dot layer 620.

In an embodiment, a fixed point PP at which the upper surface 640us of the first organic capping layer 640 contacts a sidewall of the second bank opening 502 may coincide with or be adjacent to a point at which an interface between the first bank layer 510 and the second bank layer 520 contacts the sidewall of the second bank opening 502. For example, the fixed point PP may coincide with or be located adjacent to a point at which a surface of the sidewall of the second bank opening 502 changes from lyophilic to lyophobic. Because a surface of the first bank layer 510 is lyophilic and has a same or similar surface energy as the upper surface 620us of the second quantum dot layer 620, the first organic capping layer 640 may be uniformly distributed to have the constant thickness ct on the upper surface 620us of the second quantum dot layer 620. In an embodiment, the thickness ct of the first organic capping layer 640 may be in a range of about 0.1 μm to about 3 μm.

The first organic capping layer 640 may prevent or reduce reduction in light conversion efficiency due to exposure of the second quantum dot layer 620 to light and/or oxygen before an inorganic capping layer PVL to be described later is formed. For example, when quantum dots including InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or any mixture thereof are exposed to light and/or oxygen due to a structure of a shell, light conversion efficiency may rapidly decrease. Accordingly, in the display apparatus according to an embodiment, the first organic capping layer 640 prevents or reduces reduction of light conversion efficiency of the second quantum dot layer 620 so that a high-quality image may be displayed.

The blue light Lb generated in the third light-emitting diode LED3 may be emitted to the outside without wavelength conversion. In an embodiment, the transmissive layer 630 may be located in the third bank opening 503 of the bank layer 500 overlapping the third pixel electrode 313. The transmissive layer 630 may overlap the third pixel electrode 313 when viewed from the direction (e.g., a z-axis direction) perpendicular to the first substrate 100. The transmissive layer 630 may include a photosensitive polymer having light transmittance and scattering particles.

The inorganic capping layer PVL may be located on the bank layer 500 to cover the first quantum dot layer 610, the first organic capping layer 640, and the transmissive layer 630. The inorganic capping layer PVL may include an inorganic insulating material, such as silicon oxide, silicon nitride, and/or silicon oxynitride.

The color filter layer 800 may be located on a lower surface of the second substrate 900 in a direction (e.g., a −z direction) to the first substrate 100. In the disclosure, when an element is located on the lower surface of the second substrate 900 in the direction (e.g., a −z direction) to the first substrate 100, it may denote that the element is formed on the second substrate 900 and the second substrate 900 is flipped and bonded to be located between the first substrate 100 and the second substrate 900. The color filter layer 800 may include the first to third filter openings 801, 802, and 803. The first to third filter openings 801, 802, and 803 of the color filter layer 800 may correspond to the first to third light-emitting diodes LED1, LED2, and LED3, respectively.

The color filter layer 800 may include the first color filter layer 810 transmitting only light of a wavelength in a range of about 625 nm to about 780 nm, the second color filter layer 820 transmitting only light of a wavelength in a range of about 495 nm to about 570 nm, and the third color filter layer 830 transmitting only light of a wavelength in a range of about 450 nm to about 495 nm.

The first color filter layer 810 may include an opening corresponding to the second pixel electrode 312 and the third pixel electrode 313. The second color filter layer 820 may include an opening corresponding to the first pixel electrode 311 and the third pixel electrode 313. The third color filter layer 830 may include an opening corresponding to the first pixel electrode 311 and the second pixel electrode 312. For example, a first filter opening 801 defined by overlapping the opening of the second color filter layer 820 and the opening of the third color filter layer 830 may be located on the first quantum dot layer 610, and the first color filter layer 810 may fill the first filter opening 801 described above. A second filter opening 802 defined by overlapping the opening of the first color filter layer 810 and the opening of the third color filter layer 830 may be located on the second quantum dot layer 620, and the second color filter layer 820 may fill the second filter opening 802 described above. A third filter opening 803 defined by the opening of the first color filter layer 810 and the opening of the second color filter layer 820 may be located on the transmissive layer 630, and the third color filter layer 830 may fill the third filter opening 803 described above.

At least two layers from among the first color filter layer 810, the second color filter layer 820, and the third color filter layer 830 may overlap each other in an area between the first to third filter openings 801, 802, and 803. An area in which the at least two layers from among the first color filter layer 810, the second color filter layer 820, and the third color filter layer 830 may serve as a black matrix. Accordingly, when viewed from the direction perpendicular to the first substrate 100, a shape and size of the red sub-pixel Pr may be defined by the first filter opening 801. Similarly, a shape and size of the green sub-pixel Pg may be defined by the second filter opening 802, and a shape and size of the blue sub-pixel Pb may be defined by the third filter opening 803.

The first color filter layer 810 to the third color filter layer 830 described above may increase color purity of light emitted to the outside so that the quality of a displayed image may be improved. The first color filter layer 810 to the third color filter layer 830 may reduce external reflection by reducing a ratio that external light incident to the display apparatus from the outside is reflected by the first pixel electrode 311 to the third pixel electrode 313 and emitted to the outside.

The low-refractive index layer 700 may be located between the color filter layer 800, and the bank layer 500 and the color conversion-transmissive layer 600. The low-refractive index layer 700 may include an inorganic protective layer 720 and an organic low-refractive index layer 710. The inorganic protective layer 720 may include an inorganic material, such as silicon oxide, silicon nitride, and silicon oxynitride, and may be formed by CVD. The inorganic protective layer 720 may prevent impurities from permeating into a lower surface of the organic low-refractive index layer 710 in the direction (e.g., a −z direction) to the first substrate 100. The organic low-refractive index layer 710 may have a refractive index of about 1.2. Scattered light passing through the color conversion-transmissive layer 600 may be totally reflected at an interface of the organic low-refractive index layer 710 and re-scattered within the color conversion-transmissive layer 600. Accordingly, the low-refractive index layer 700 may change a lateral side scattering into a front side scattering so that luminance may be improved.

The first substrate 100 and the second substrate 900 may be bonded together outside a display area by a bonding member, such as a sealant. When desirable, a filler (not shown) may fill a space between a stacked body on the first substrate 100 and a stacked body on the second substrate 900. For example, the filler may fill a space between the encapsulation layer 400 and the low-refractive index layer 700. Such a filler may include a resin, such as acrylic or epoxy.

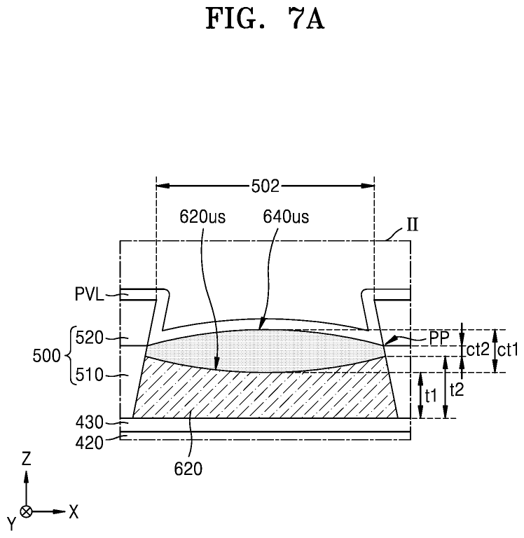

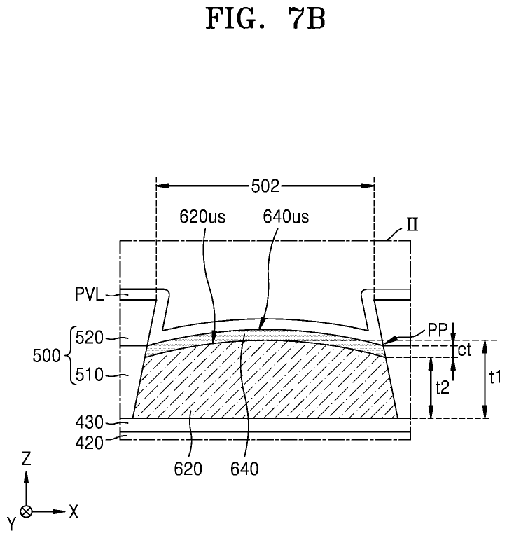

FIGS. 7A and 7B are each a schematic cross-sectional view of a part of the display apparatus according to an embodiment. FIGS. 7A and 7B correspond to enlarged cross-sections of region II in FIG. 5. FIGS. 7A and 7B differ from FIG. 6, at least in cross-sectional shapes of the second quantum dot layer 620 and the first organic capping layer 640. Hereinafter, descriptions of elements that are same or similar as or to each other may be omitted, and only differences may be described.

Referring to FIG. 7A, the second quantum dot layer 620 may have a concave shape in which a thickness t1 of a central portion is less than a thickness t2 of a peripheral portion adjacent to a sidewall of the second bank opening 502. Depending on an amount of a material for forming the first organic capping layer 640 sprayed into the second bank opening 502 by using an inkjet printing method, the first organic capping layer 640 may have a convex shape in which a thickness ct1 of a central portion is greater than a thickness ct2 of a peripheral portion adjacent to a sidewall of the second bank opening 502. Each of the thickness ct1 of the central portion of the first organic capping layer 640 and the thickness ct2 of the peripheral portion may be in a range of about 0.1 nm to about 3 nm.

Referring to FIG. 7B, depending on an amount of a material for forming the second quantum dot layer 620 sprayed into the second bank opening 502 by using an inkjet printing method, the second quantum dot layer 620 may have a convex shape in which the thickness t1 of the central portion is greater than the thickness t2 of the peripheral portion adjacent to the sidewall of the second bank opening 502. The first organic capping layer 640 may have the constant thickness ct on the upper surface 620us of the second quantum dot layer 620. For example, the upper surface 640us of the first organic capping layer 640 may have a same or similar shape as or to the upper surface 620us of the second quantum dot layer 620.

Because a surface of the second bank layer 520 is lyophobic, as shown in FIGS. 7A and 7B, the fixed point PP at which the upper surface 640us of the first organic capping layer 640 contacts the sidewall of the second bank opening 502 may coincide with or be adjacent to the point at which the interface between the first bank layer 510 and the second bank layer 520 contacts the sidewall of the second bank opening 502.

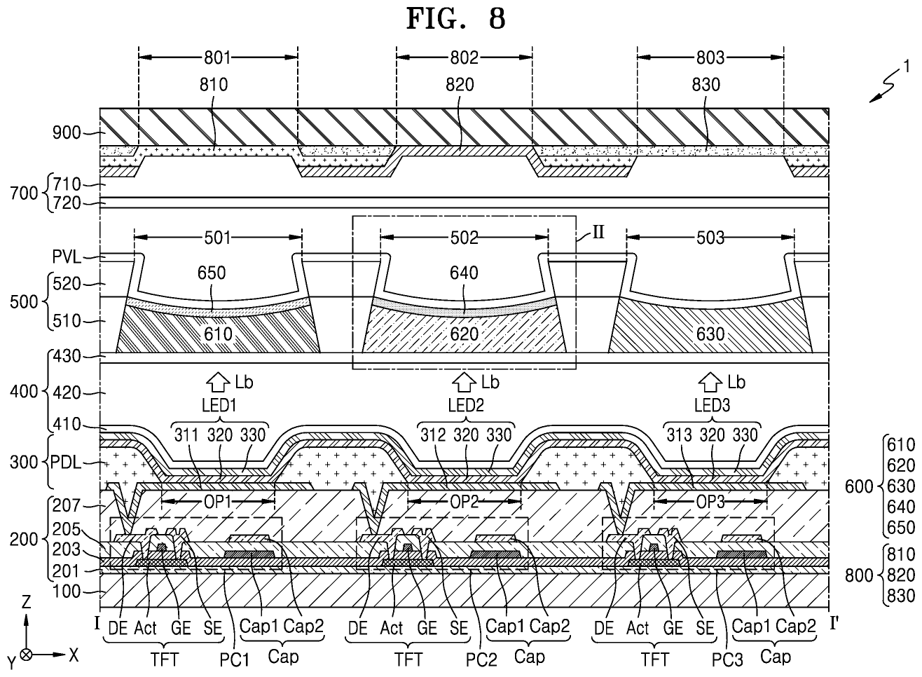

FIG. 8 is a schematic cross-sectional view of a part of the display apparatus according to an embodiment. FIG. 8 may correspond to a cross-section of the display apparatus, taken along line I-I′ in FIG. 1. FIG. 8 differs from FIG. 5, at least in that a second organic capping layer 650 is located on the first quantum dot layer 610 in the first bank opening 501. Hereinafter, descriptions of elements that are same or similar as or to each other may be omitted, and only differences may be described.

The second organic capping layer 650 may be located on the first quantum dot layer 610 in the first bank opening 501. The second organic capping layer 650 may overlap the first pixel electrode 311 when viewed from the direction (e.g., a z-axis direction) perpendicular to the first substrate 100.

The second organic capping layer 650 may be a photosensitive polymer. For example, a monomer for forming the second organic capping layer 650 may be a photosensitive acryl-based resin. In an embodiment, the monomer for forming the second organic capping layer 650 may include hexamethylene diacrylate, tetraethylene glycol diacrylate, dipropylene glycol diacrylate, tripropylene glycol diacrylate, or any mixture thereof. In an embodiment, the first organic capping layer 640 and the second organic capping layer 650 may include a same material as each other.

As shown in FIG. 8, the first quantum dot layer 610 may have a concave shape in which a thickness of a central portion is less than a thickness of a peripheral portion adjacent to a sidewall of the first bank opening 501. The second organic capping layer 650 may have a constant thickness on an upper surface of the first quantum dot layer 610. A fixed point at which the upper surface of the second organic capping layer 650 contacts the sidewall of the first bank opening 501 may coincide with or be adjacent to a point at which the interface between the first bank layer 510 and the second bank layer 520 contacts the sidewall of the first bank opening 501. In an embodiment, the thickness of the second organic capping layer 650 may be in a range of about 0.1 μm to about 3 μm.

In another embodiment, the first quantum dot layer 610 and the second organic capping layer 650 may have a similar structure to a structure of the second quantum dot layer 620 and the first organic capping layer 640 shown in FIG. 7A. For example, the first quantum dot layer 610 may have a convex shape in which a thickness of a central portion is greater than a thickness of a peripheral portion adjacent to a sidewall of the first bank opening 501, and the second organic capping layer 650 may have a constant thickness on the upper surface of the first quantum dot layer 610.

In another embodiment, the first quantum dot layer 610 and the second organic capping layer 650 may have a similar structure to a structure of the second quantum dot layer 620 and the first organic capping layer 640 shown in FIG. 7B. The first quantum dot layer 610 may have a concave shape in which a thickness of a central portion is less than a thickness of a peripheral portion adjacent to the sidewall of the first bank opening 501, and the second organic capping layer 650 may have a convex shape in which a thickness of a central portion is greater than a thickness of a peripheral portion adjacent to the sidewall of the first bank opening 501.

The second organic capping layer 650 may prevent or reduce reduction in light conversion efficiency due to exposure of the first quantum dot layer 610 to light and/or oxygen before an inorganic capping layer PVL is formed. For example, although quantum dots including InP have relatively high stability, when a delay time prior to formation of the inorganic capping layer PVL exceeds a day, light conversion efficiency may decrease. Accordingly, in the display apparatus according to an embodiment, the first organic capping layer 640 is located on the second quantum dot layer 620, and the second organic capping layer 650 is located on the first quantum dot layer 610, and thus, even when a delay time increases during a process, a decrease in light conversion efficiency of the first and second quantum dot layers 610 and 620 may be prevented or reduced.

On the other hand, the transmissive layer 630 does not include quantum dots, and thus, an organic capping layer may not be located on the transmissive layer 630.

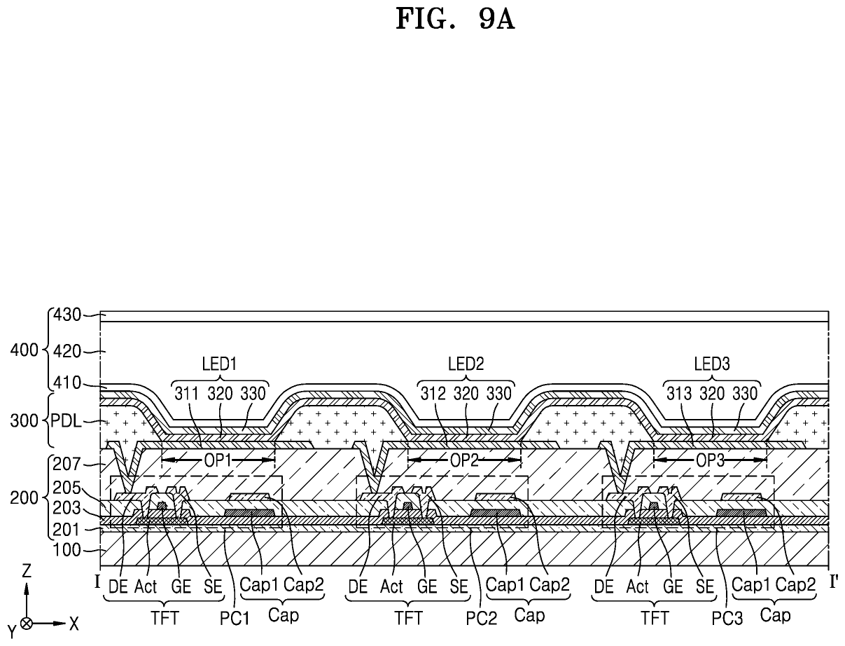

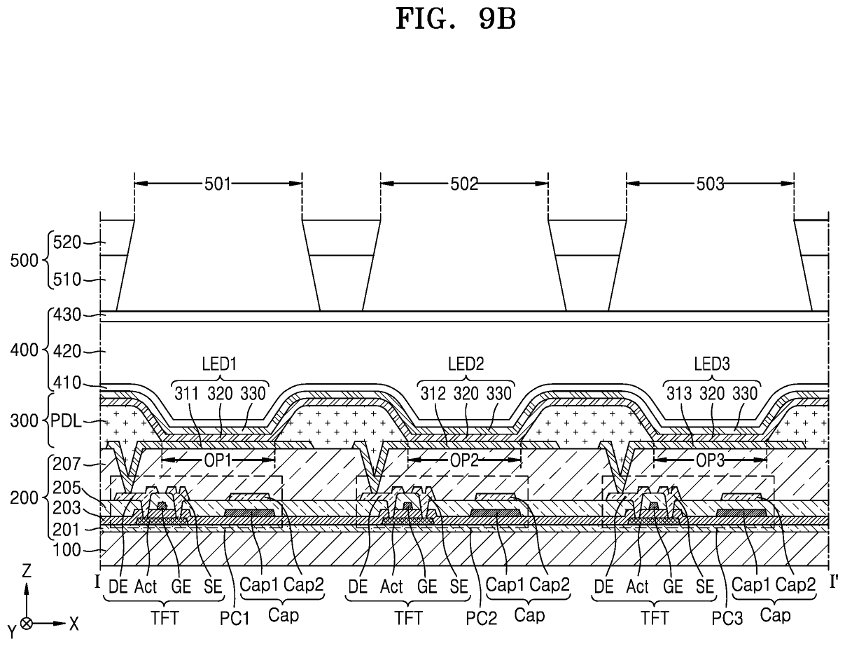

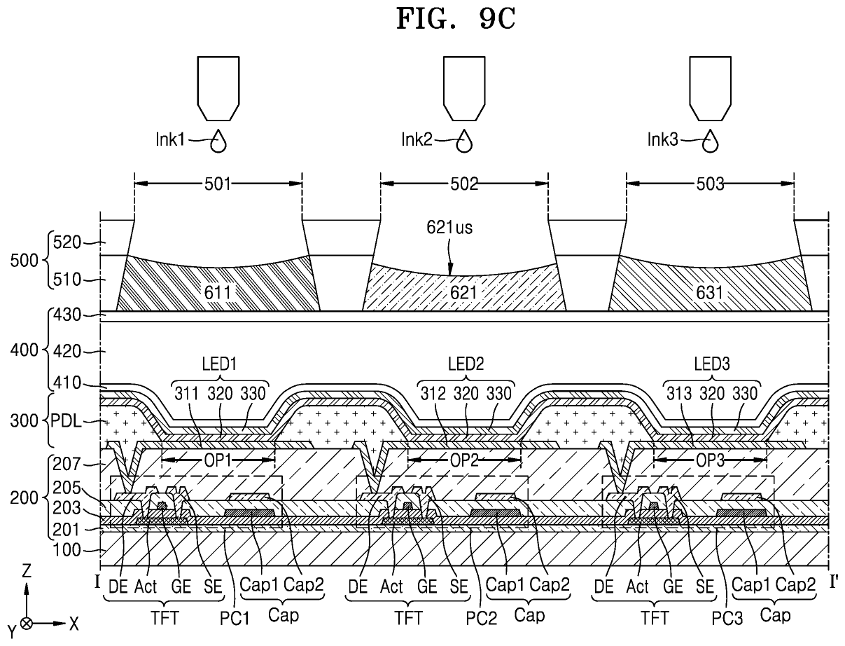

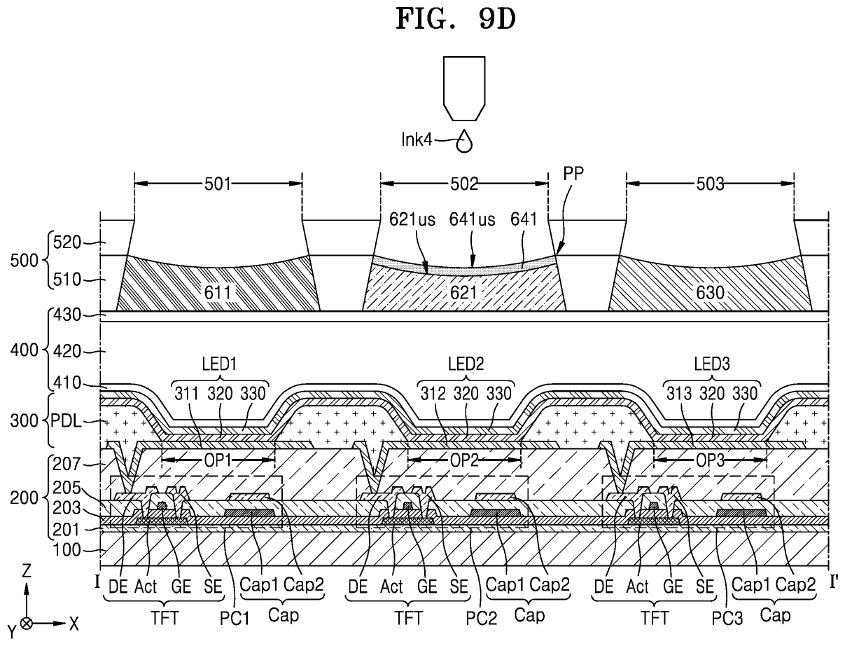

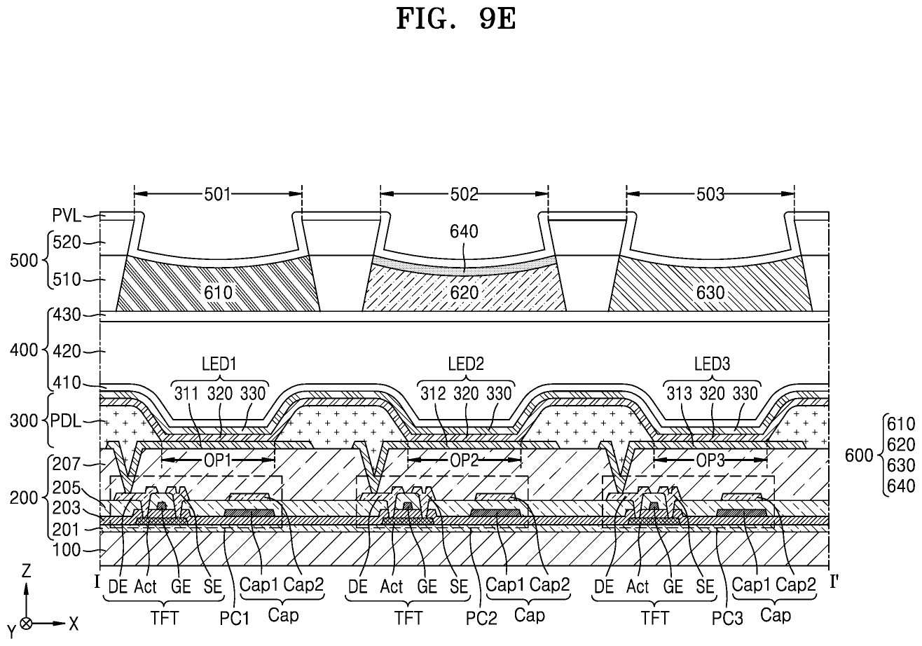

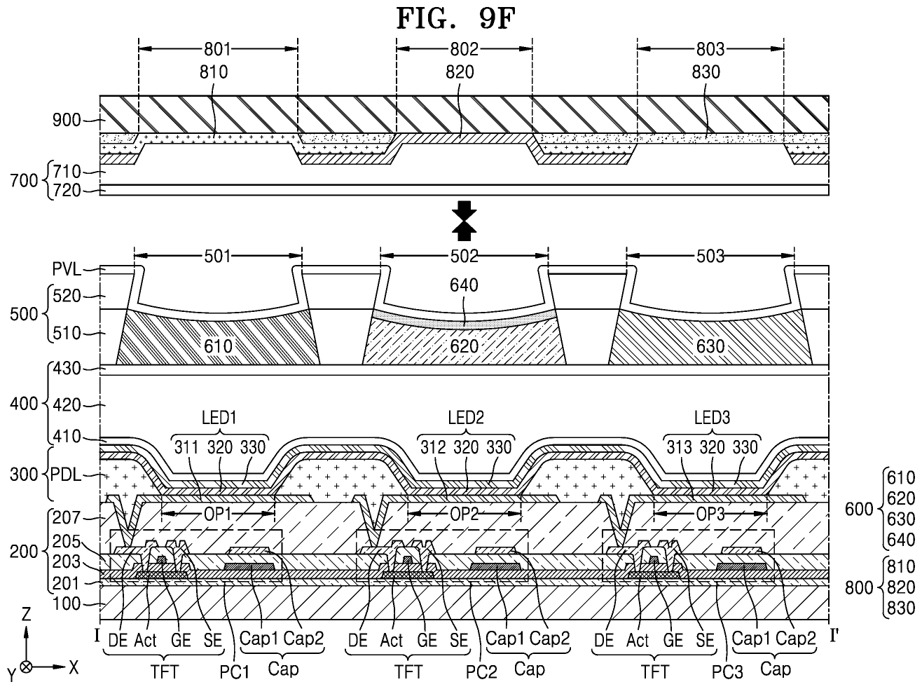

FIGS. 9A to 9F are schematic cross-sectional views sequentially illustrating some operations of a method of manufacturing the display apparatus, according to an embodiment.

Referring to FIG. 9A, the first substrate 100, and the circuit layer 200, the light-emitting diode layer 300, and the encapsulation layer 400 on the first substrate 100 may be prepared.

The circuit layer 200 may include first to third sub-pixel circuits PC1, PC2, and PC3, and the first to third sub-pixel circuits PC1, PC2, and PC3 may be electrically connected to first to third light-emitting diodes LED1, LED2, and LED3 of a light-emitting diode layer 300, respectively. The circuit layer 200 may include the buffer layer 201, the gate insulating layer 203, the interlayer insulating layer 205, and the planarization layer 207 on, under, and/or between each of the elements of the first to third sub-pixel circuits PC1, PC2, and PC3.

The first light-emitting diode LED1 may include the first pixel electrode 311, the opposite electrode 330, and the intermediate layer 320 located between the first pixel electrode 311 and the opposite electrode 330, and an emission layer. The second light-emitting diode LED2 may include the second pixel electrode 312, the opposite electrode 330, and the intermediate layer 320 located between the second pixel electrode 312 and the opposite electrode 330, and an emission layer. Similarly, the third light-emitting diode LED3 may include the third pixel electrode 313, the opposite electrode 330, and the intermediate layer 320 located between the third pixel electrode 313 and the opposite electrode 330 and an emission layer.

The pixel-defining layer PDL may be disposed on the planarization layer 207. The pixel-defining layer PDL may include pixel openings respectively corresponding to the first to third pixel electrodes 311, 312, and 313.

The encapsulation layer 400 may cover the first to third light-emitting diodes LED1, LED2, and LED3. The encapsulation layer 400 may include the first inorganic encapsulation layer 410, the second inorganic encapsulation layer 430, and the organic encapsulation layer 420 therebetween. The upper surface of the organic encapsulation layer 420 may have an approximately flat shape, and accordingly, the second inorganic encapsulation layer 430 on the organic encapsulation layer 420 may also have an approximately flat shape.

Referring to FIG. 9B, the bank layer 500 may be formed on the second inorganic encapsulation layer 430. The bank layer 500 may include the first bank layer 510 and the second bank layer 520 located on the first bank layer 510. A surface of the first bank layer 510 may be lyophilic, and a surface of the second bank layer 520 may be lyophobic.

The bank layer 500 may include the first to third bank openings 501, 502, and 503. The first to third bank openings 501, 502, and 503 of the bank layer 500 may correspond to the first to third light-emitting diodes LED1, LED2, and LED3, respectively. The first bank opening 501 of the bank layer 500 may correspond to the first pixel opening OP1 of the pixel-defining layer PDL exposing the first pixel electrode 311, the second bank opening 502 may correspond to the second pixel opening OP2 of the pixel-defining layer PDL exposing the second pixel electrode 312, and the third bank opening 503 may correspond to the third pixel opening OP3 of the pixel-defining layer PDL exposing the third pixel electrode 313.

Because the first to third bank openings 501, 502, and 503 are formed on the first substrate 100 by using a photolithography process, such as exposure and development, an area of a surface of the bank layer 500 in a direction toward the first substrate 100 may be less than an area of a surface in a direction toward the second substrate 900. Accordingly, as shown in FIG. 9B, the bank layer 500 may have a reverse-tapered shape with reference to the first substrate 100.

Referring to FIG. 9C, by using an inkjet printing process, a first ink Ink1 may be sprayed into the first bank opening 501, a second ink Ink2 may be sprayed into the second bank opening 502, and a third ink Ink3 may be sprayed into the third bank opening 503.

The first ink Ink1 may include a material 611 forming the first quantum dot layer 610. In an embodiment, the first ink Ink1 may include a photosensitive monomer, quantum dots, and scattering particles. Here, quantum dots included in the first ink Ink1 may include a material selected from among Group II-VI semiconductor compounds, Group III-V semiconductor compounds, Group III-VI semiconductor compounds, Group I-III-VI semiconductor compounds, Group IV-VI semiconductor compounds, or any mixture thereof.

The second ink Ink2 may include a material 621 forming the second quantum dot layer 620. In an embodiment, the second ink Ink2 may include a photosensitive monomer, quantum dots, and scattering particles. Here, the quantum dots included in the second ink Ink2 may include InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or any mixture thereof.

The third ink Ink3 may include a material 631 forming the transmissive layer 630. In an embodiment, the third ink Ink3 may include a photosensitive monomer, quantum dots, and scattering particles.

The material 611 forming the first quantum dot layer 610 may be located in the first bank opening 501. The fixed point PP at which an upper surface of the material 611 forming the first quantum dot layer 610 contacts the sidewall of the first bank opening 501 may coincide with or be adjacent to a point at which the interface between the first bank layer 510 and the second bank layer 520 contacts the sidewall of the first bank opening 501. A shape of the upper surface of the material 611 forming the first quantum dot layer 610 may be determined by adjusting a sprayed amount of the first ink Ink1. For example, when the sprayed amount of the first ink Ink1 is small, the upper surface of the material 611 forming the first quantum dot layer 610 may have a concave shape. When the sprayed amount of the first ink Ink1 is large, the upper surface of the material 611 forming the first quantum dot layer 610 may have a convex shape.

The material 621 forming the second quantum dot layer 620 may be located in the second bank opening 502. Similarly, a shape of an upper surface of the material 621 forming the second quantum dot layer 620 may be determined by adjusting a sprayed amount of the second ink Ink2.

The material 631 forming the transmissive layer 630 may be located in the third bank opening 503. A shape of an upper surface of the material 631 forming the transmissive layer 630 may be determined by adjusting a sprayed amount of the third ink Ink3.

Referring to FIG. 9D, a fourth ink Ink4 may be sprayed into the second bank opening 502 by using an inkjet printing process.

The fourth ink Ink4 may include a material 641 forming the first organic capping layer 640. The material 641 forming the first organic capping layer 640 may be a photosensitive acryl-based monomer. In an embodiment, the material 641 forming the first organic capping layer 640 may include hexamethylene diacrylate, tetraethylene glycol diacrylate, dipropylene glycol diacrylate, tripropylene glycol diacrylate, or any mixture thereof.

In an embodiment, the photosensitive monomer included in the material 621 forming the second quantum dot layer 620 may be a same material as the material 641 forming the first organic capping layer 640.

In an embodiment, a viscosity of the fourth ink Ink4 may be in a range of about 1 cps to about 30 cps.

A thickness of the material 641 forming the first organic capping layer 640 may be in a range of about 0.1 nm to about 3 nm. When the thickness of the material 641 forming the first organic capping layer 640 is less than 0.1 nm, the material 641 forming the first organic capping layer 640 may not be sufficiently applied onto the material 621 forming the second quantum dot layer 620. When a thickness of the material 641 forming the first organic capping layer 640 is greater than 3 nm, curing efficiency may decrease.

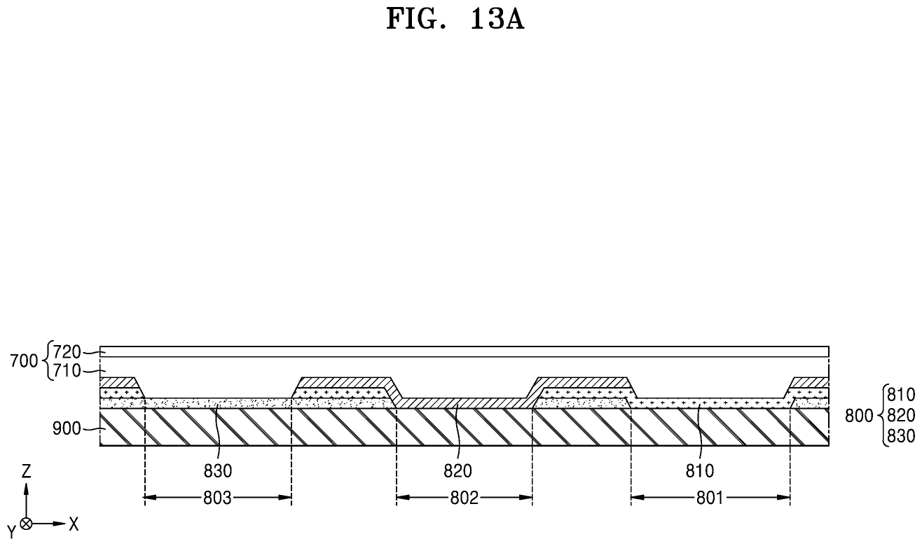

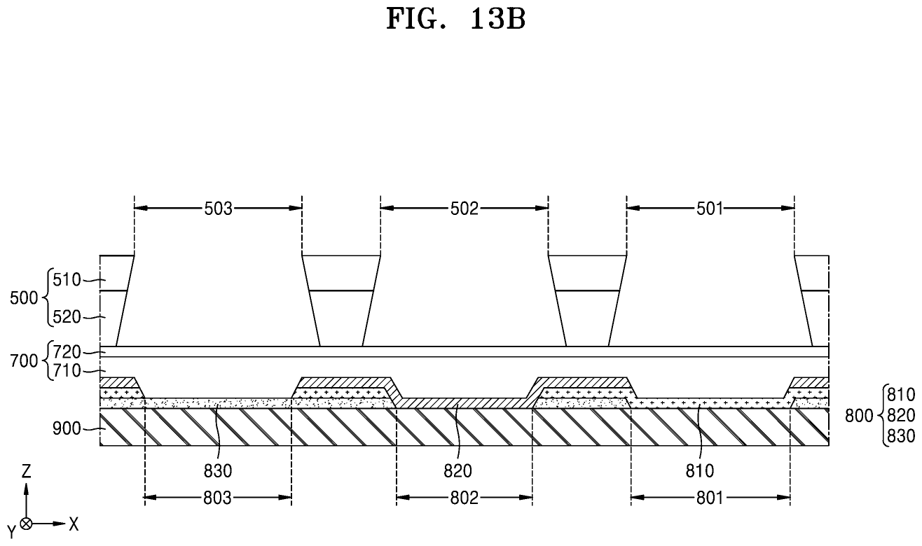

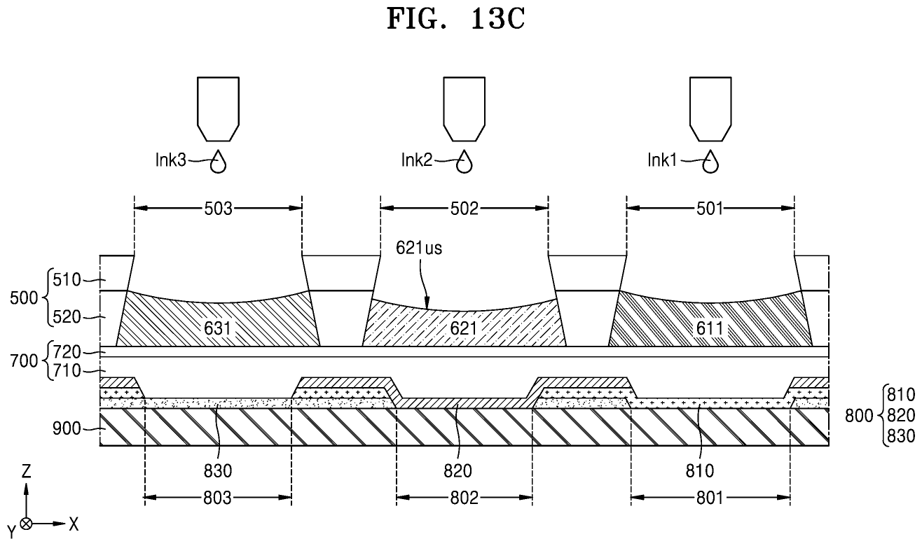

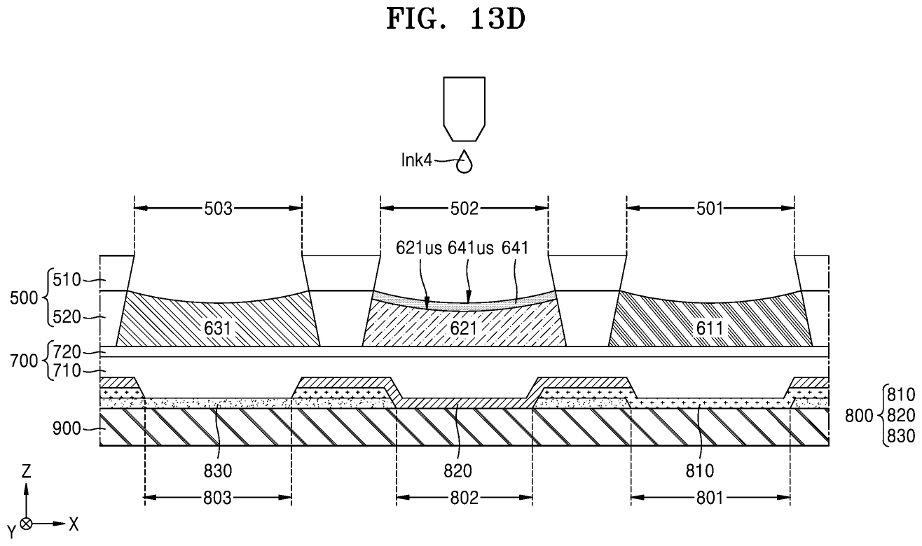

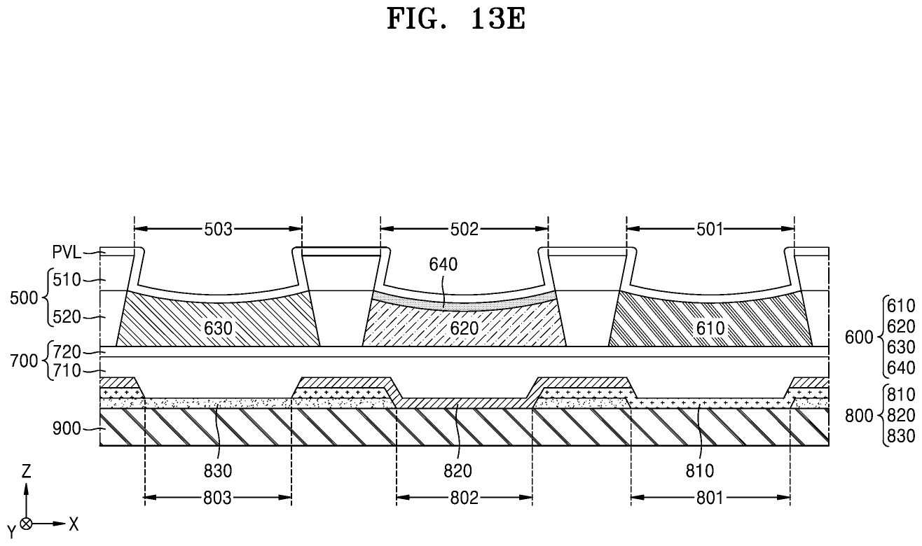

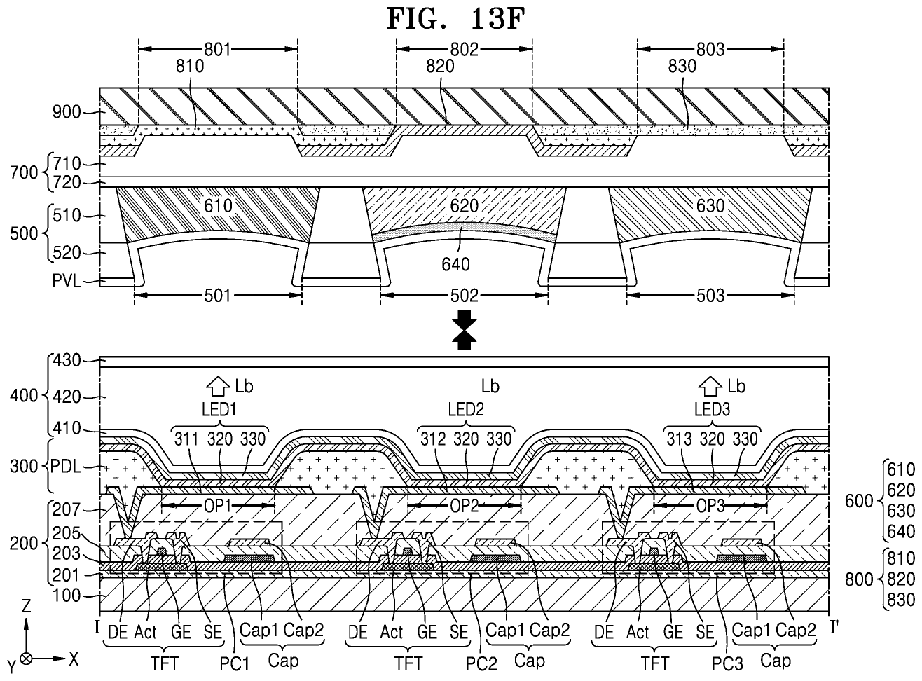

In an embodiment, the material 641 forming the first organic capping layer 640 may have a constant thickness, as shown in FIG. 13D. For example, an upper surface 641us of the material 641 forming the first organic capping layer 640 may have a similar shape to a shape of an upper surface 621us of the material 621 forming the second quantum dot layer 620.

In another embodiment, the material 641 forming the first organic capping layer 640 may have a convex shape in which a thickness of a central portion is greater than a thickness of a peripheral portion adjacent to a sidewall of the second bank opening 502.

Although not shown in FIG. 9D, a material forming a second organic capping layer may be applied onto the material 611 forming the first quantum dot layer 610 by spraying the fourth ink Ink4 into the first bank opening 501.

Although not shown in FIG. 9E, an infrared ray may be irradiated to the material 611 forming the first quantum dot layer 610, the material 621 forming the second quantum dot layer 620, the material 631 forming the transmissive layer 630, and the material 641 forming the first organic capping layer 640, so that the first quantum dot layer 610, the second quantum dot layer 620, the transmissive layer 630, and the first organic capping layer 640 may be formed.

Photosensitive monomers included in the material 611 forming the first quantum dot layer 610, the material 621 forming the second quantum dot layer 620, the material 631 forming the transmissive layer 630, and the material 641 forming the first organic capping layer 640 may polymerize with each other and form a polymer. Accordingly, the material 611 forming the first quantum dot layer 610, the material 621 forming the second quantum dot layer 620, the material 631 forming the transmissive layer 630, and the material 641 forming the first organic capping layer 640 may lose the flexibility thereof and be cured.

The second quantum dot layer 620 and the first organic capping layer 640 may be crosslinked to each other and formed. Until the inorganic capping layer PVL is formed, a decrease in light conversion efficiency by exposure of the second quantum dot layer 620 to light and/or oxygen may be prevented or reduced by the first organic capping layer 640.

Thereafter, by using CVD, the inorganic capping layer PVL may be formed on the bank layer 500 to cover the first quantum dot layer 610, the first organic capping layer 640, and the transmissive layer 630.

Referring to FIG. 9F, the second substrate 900, in which the color filter layer 800 and the low-refractive index layer 700 are located on a lower surface thereof in a direction (e.g., a −z direction) to the first substrate 100, may be bonded to the first substrate 100.

The color filter layer 800 may be located on the lower surface of the second substrate 900 in the direction (e.g., a −z direction) to the first substrate 100. The color filter layer 800 may include the first to third filter openings 801, 802, and 803. The first to third filter openings 801, 802, and 803 of the color filter layer 800 may correspond to the first to third light-emitting diodes LED1, LED2, and LED3, respectively.

The color filter layer 800 may include the first color filter layer 810 transmitting only light of a wavelength in a range of about 625 nm to about 780 nm, the second color filter layer 820 transmitting only light of a wavelength in a range of about 495 nm to about 570 nm, and the third color filter layer 830 transmitting only light of a wavelength in a range of about 450 nm to about 495 nm. The third color filter layer 830 may be formed on a lower surface of the second substrate 900 in the direction (e.g., a −z direction) to the first substrate 100, the first color filter layer 810 may be formed on a lower surface of the third color filter layer 830, and the second color filter layer 820 may be formed on a lower surface of the first color filter layer 810.

At least two layers from among the first color filter layer 810, the second color filter layer 820, and the third color filter layer 830 may be formed to overlap each other in an area between the first to third filter openings 801, 802, and 803.

The low-refractive index layer 700 may include the organic low-refractive index layer 710 and the inorganic protective layer 720. The organic low-refractive index layer 710 may include an organic material having a refractive index of about 1.2, and may directly contact the color filter layer 800. The inorganic protective layer 720 may include an inorganic material, such as silicon oxide, silicon nitride, and silicon oxynitride, and may be formed by CVD.

The first substrate 100 and the second substrate 900 may be bonded together outside a display area by a bonding member, such as a sealant. When desirable, a filler (not shown) may fill a space between a stacked body on the first substrate 100 and a stacked body on the second substrate 900.

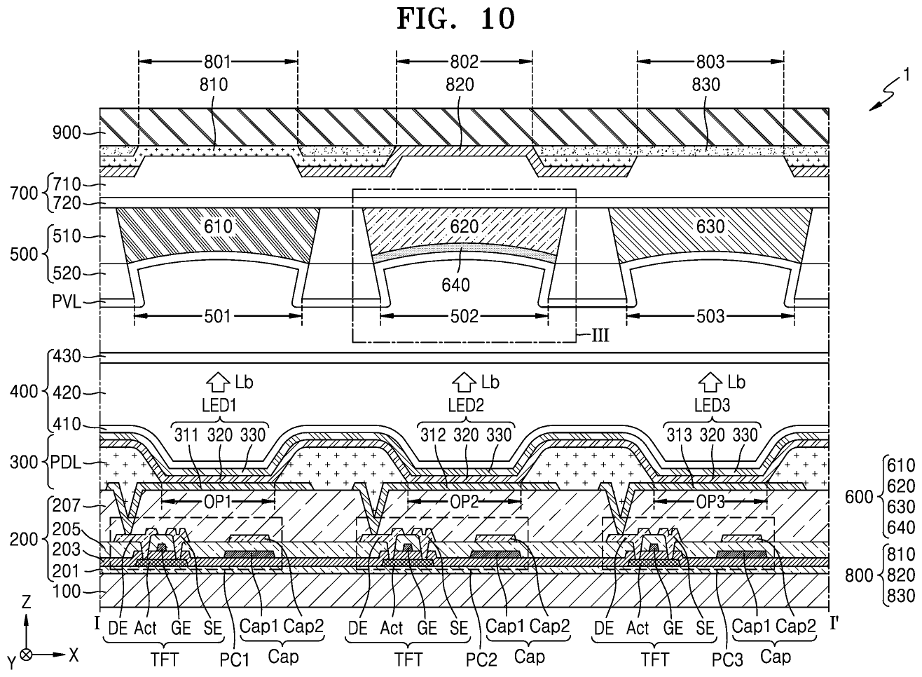

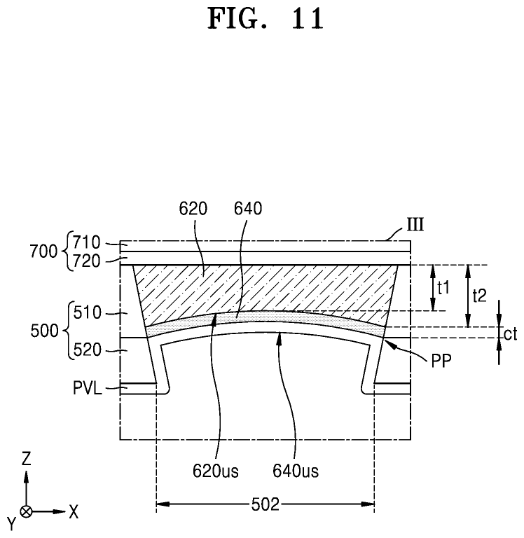

FIG. 10 is a schematic cross-sectional view of a part of the display apparatus according to an embodiment, and FIG. 11 is an enlarged schematic cross-sectional view of region III of the display apparatus shown in FIG. 10. FIG. 10 differs from FIG. 5, at least in that the bank layer 500 and the color conversion-transmissive layer 600 are formed on a lower surface of the low-refractive index layer 700 in the direction (e.g., a −z direction) to the first substrate 100. Hereinafter, descriptions of elements that are same or similar as or to each other may be omitted, and only differences may be described.

Referring to FIG. 10, the color filter layer 800 may be located on the lower surface of the second substrate 900 in the direction (e.g., a −z direction) to the first substrate 100. The color filter layer 800 may include the first to third filter openings 801, 802, and 803. The first to third filter openings 801, 802, and 803 of the color filter layer 800 may correspond to the first to third light-emitting diodes LED1, LED2, and LED3, respectively.

The low-refractive index layer 700 may be located on the lower surface of the color filter layer 800 in the direction (e.g., a −z direction) to the first substrate 100. The low-refractive index layer 700 may include the inorganic protective layer 720 and the organic low-refractive index layer 710. The organic low-refractive index layer 710 may have a refractive index of about 1.2. The organic low-refractive index layer 710 may directly contact the color filter layer 800, and a lower surface of the organic low-refractive index layer 710 in the direction (e.g., a −z direction) to the first substrate 100 may have an approximately flat shape.

The inorganic protective layer 720 may include an inorganic material, such as silicon oxide, silicon nitride, and silicon oxynitride, and may be formed by CVD. The inorganic protective layer 720 may prevent impurities from permeating into the lower surface of the organic low-refractive index layer 710 in the direction (e.g., a −z direction) to the first substrate 100.

The bank layer 500 may be disposed on a lower surface of the inorganic protective layer 720 in the direction (e.g., a −z direction) to the first substrate 100. The first to third bank openings 501, 502, and 503 of the bank layer 500 may correspond to the first to third light-emitting diodes LED1, LED2, and LED3, respectively. The first bank opening 501 of the bank layer 500 may correspond to the first pixel opening OP1 of the pixel-defining layer PDL exposing the first pixel electrode 311, the second bank opening 502 may correspond to the second pixel opening OP2 of the pixel-defining layer PDL exposing the second pixel electrode 312, and the third bank opening 503 may correspond to the third pixel opening OP3 of the pixel-defining layer PDL exposing the third pixel electrode 313.

For example, when viewed from the direction (e.g., a z-axis direction) perpendicular to the first substrate 100, the first bank opening 501 of the bank layer 500 may overlap the first pixel opening OP1 of the pixel-defining layer PDL exposing the first pixel electrode 311, the second bank opening 502 may overlap the second pixel opening OP2 of the pixel-defining layer PDL exposing the second pixel electrode 312, and the third bank opening 503 may overlap the third pixel opening OP3 of the pixel-defining layer PDL exposing the third pixel electrode 313. Similarly, the first bank opening 501 of the bank layer 500 may correspond to the first pixel electrode 311, the second bank opening 502 of the bank layer 500 may correspond to the second pixel electrode 312, and the third bank opening 503 of the bank layer 500 may correspond to the third pixel electrode 313.

Because the bank layer 500 is formed on the second substrate 900 through a process, such as exposure and development, it may be shown such that the bank layer 500 has a reverse-tapered shape with reference to the second substrate 900. For example, the area of the surface of the bank layer 500 in the direction toward the first substrate 100 may be greater than the area of the surface of the bank layer 500 in the direction toward the second substrate 900.

The bank layer 500 may include the first bank layer 510 having a lyophilic surface and the second bank layer 520 having a lyophobic surface. For example, the first bank layer 510 having the lyophilic surface may be located on the lower surface of the inorganic protective layer 720 in the direction (e.g., a −z direction) to the first substrate 100, and the second bank layer 520 having the lyophobic surface may be located on the lower surface of the first bank layer 510 in the direction (e.g., a −z direction) to the first substrate 100.

The blue light Lb generated by the first light-emitting diode LED1 may be converted into the red light Lr by the first quantum dot layer 610 located in the first bank opening 501, and emitted to the outside. The first quantum dot layer 610 described above may overlap the first pixel electrode 311 when viewed from the direction (e.g., a z-axis direction) perpendicular to the first substrate 100. The first quantum dot layer 610 may include a photosensitive polymer, quantum dots, and scattering particles, which have light-transmitting properties.

The quantum dots of the first quantum dot layer 610 may include a material selected from among Group II-VI semiconductor compounds, Group III-V semiconductor compounds, Group III-VI semiconductor compounds, Group I-III-VI semiconductor compounds, Group IV-VI semiconductor compounds, or any mixture thereof.

The blue light Lb generated by the second light-emitting diode LED2 may be converted into the green light Lg by the second quantum dot layer 620 located in the second bank opening 502, and emitted to the outside. The second quantum dot layer 620 described above may overlap the second pixel electrode 312 when viewed from the direction (e.g., a z-axis direction) perpendicular to the first substrate 100. The second quantum dot layer 620 may include a photosensitive polymer, quantum dots, and scattering particles, which have light-transmitting properties.

As described above, the quantum dots of the second quantum dot layer 620 may include a material selected from among Group III-V compounds, Group III-VI compounds, Group II-VI compounds, Group I-III-VI compounds, and a mixture thereof. In an embodiment, the second quantum dot layer 620 may include InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or any mixture thereof.

The first organic capping layer 640 may be located on a lower surface of the second quantum dot layer 620 in the direction (e.g., a −z direction) to the first substrate 100 within the second bank opening 502. The first organic capping layer 640 described above may overlap the second pixel electrode 312 when viewed from the direction (e.g., a z-axis direction) perpendicular to the first substrate 100.

The first organic capping layer 640 may be a photosensitive polymer. For example, a monomer for forming the first organic capping layer 640 may be photosensitive acryl-based resin. In an embodiment, the monomer for forming the first organic capping layer 640 may include hexamethylene diacrylate, tetraethylene glycol diacrylate, dipropylene glycol diacrylate, tripropylene glycol diacrylate, or any mixture thereof.

As shown in FIG. 11, with respect to the second substrate 900, the second quantum dot layer 620 may have a concave shape in which the thickness t1 of a central portion is less than the thickness t2 of a peripheral portion adjacent to the sidewall of the second bank opening 502. The first organic capping layer 640 may have the constant thickness ct on the upper surface 620us of the second quantum dot layer 620 in the direction (e.g., a −z direction) to the first substrate 100. For example, the upper surface 640us of the first organic capping layer 640 in the direction (e.g., a −z direction) to the first substrate 100 may have a same or similar shape as or to a shape of the upper surface 620us of the second quantum dot layer 620 in the direction (e.g., a −z direction) to the first substrate 100. In an embodiment, the thickness ct of the first organic capping layer 640 may be in a range of about 0.1 μm to about 3 μm.

Although not shown in FIG. 10, a second organic capping layer (not shown) may be located on the first quantum dot layer 610. The second organic capping layer may be a photosensitive polymer. In an embodiment, the first organic capping layer 640 and the second organic capping layer may include a same material as each other. In an embodiment, the thickness of the second organic capping layer may be in a range of about 0.1 μm to about 3 μm.

The inorganic capping layer PVL may be located on the bank layer 500 to cover the first quantum dot layer 610, the first organic capping layer 640, and the transmissive layer 630. The inorganic capping layer PVL may include an inorganic insulating material, such as silicon oxide, silicon nitride, and/or silicon oxynitride.

The first substrate 100 and the second substrate 900 may be bonded together outside a display area by a bonding member, such as a sealant. When desirable, a filler (not shown) may fill a space between a stacked body on the first substrate 100 and a stacked body on the second substrate 900. For example, the filler may fill a space between the encapsulation layer 400 and the inorganic capping layer PVL.

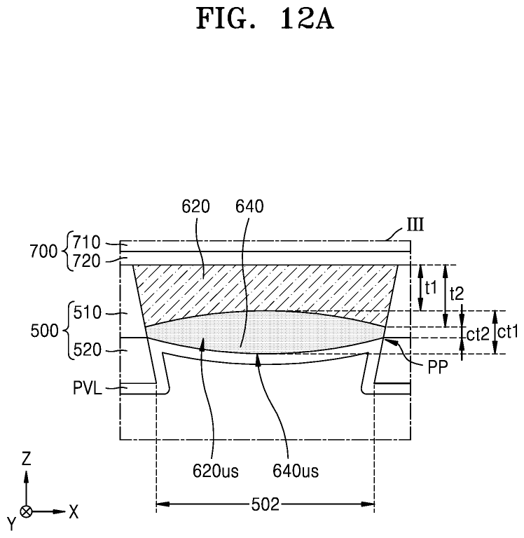

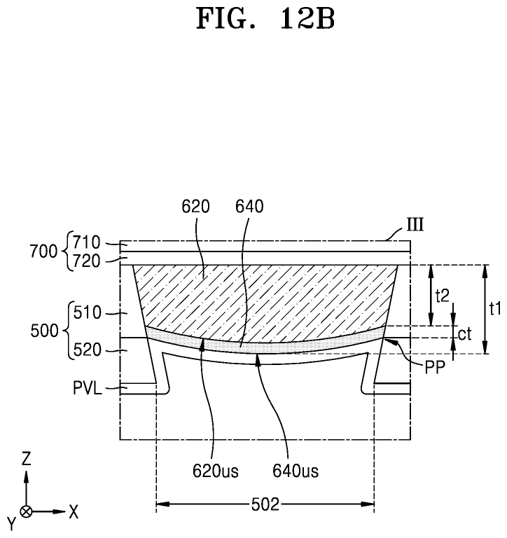

FIGS. 12A and 12B are each a schematic cross-sectional view of a part of the display apparatus according to an embodiment. FIGS. 12A and 12B differ from FIG. 11, at least in the cross-sectional shapes of the second quantum dot layer 620 and the first organic capping layer 640. Hereinafter, descriptions of elements that are same or similar as or to each other may be omitted, and only differences may be described.

Referring to FIG. 12A, with respect to the second substrate 900, the second quantum dot layer 620 may have a concave shape in which the thickness t1 of a central portion is less than the thickness t2 of a peripheral portion adjacent to the sidewall of the second bank opening 502. Depending on an amount of a material for forming the first organic capping layer 640 sprayed into the second bank opening 502 by using an inkjet printing method, the first organic capping layer 640 may have a convex shape in which a thickness ct1 of a central portion is greater than a thickness ct2 of a peripheral portion adjacent to a sidewall of the second bank opening 502. Each of the thickness ct1 of the central portion of the first organic capping layer 640 and the thickness ct2 of the peripheral portion may be in a range of about 0.1 nm to about 3 nm.

Referring to FIG. 12B, with respect to the second substrate 900, the second quantum dot layer 620 may have a convex shape in which the thickness t1 of a central portion is greater than the thickness t2 of a peripheral portion adjacent to the sidewall of the second bank opening 502. The first organic capping layer 640 may have the constant thickness ct on the upper surface 620us of the second quantum dot layer 620 in the direction (e.g., a −z direction) to the first substrate 100. For example, the upper surface 640us of the first organic capping layer 640 in the direction (e.g., a −z direction) to the first substrate 100 may have a same or similar shape as or to a shape of the upper surface 620us of the second quantum dot layer 620 in the direction (e.g., a −z direction) to the first substrate 100.

Because a surface of the second bank layer 520 is lyophobic, as shown in FIGS. 12A and 12B, the fixed point PP at which the upper surface 640us of the first organic capping layer 640 contacts the sidewall of the second bank opening 502 may coincide with or be adjacent to the point at which the interface between the first bank layer 510 and the second bank layer 520 contacts the sidewall of the second bank opening 502.

FIGS. 13A to 13F are schematic cross-sectional views sequentially illustrating some operations of a method of manufacturing the display apparatus, according to an embodiment.

Referring to FIG. 13A, the second substrate 900, the color filter layer 800 on the second substrate 900, and the low-refractive index layer 700 may be prepared.

The color filter layer 800 may include the first to third filter openings 801, 802, and 803. When the second substrate 900 and the first substrate 100 are bonded together, the first to third filter openings 801, 802, and 803 of the color filter layer 800 may correspond to the first to third light-emitting diodes LED1, LED2, and LED3 located on the first substrate 100, respectively.

The color filter layer 800 may include the first color filter layer 810 transmitting only light of a wavelength in a range of about 625 nm to about 780 nm, the second color filter layer 820 transmitting only light of a wavelength in a range of about 495 nm to about 570 nm, and the third color filter layer 830 transmitting only light of a wavelength in a range of about 450 nm to about 495 nm.

The third color filter layer 830 including openings respectively corresponding to the first pixel electrode 311 and the second pixel electrode 312 may be formed on the second substrate 900. The first color filter layer 810 including openings respectively corresponding to the second pixel electrode 312 and the third pixel electrode 313 may be formed on the third color filter layer 830. The second color filter layer 820 including openings respectively corresponding to the first pixel electrode 311 and the third pixel electrode 313 may be formed on the first color filter layer 810. The first filter opening 801 defined by overlapping the opening of the second color filter layer 820 and the opening of the third color filter layer 830 may be located on the first quantum dot layer 610, and the first color filter layer 810 may fill the first filter opening 801 described above. The second filter opening 802 defined by overlapping the opening of the first color filter layer 810 and the opening of the third color filter layer 830 may be located on the second quantum dot layer 620, and the second color filter layer 820 may fill the second filter opening 802 described above. The third filter opening 803 defined by the opening of the first color filter layer 810 and the opening of the second color filter layer 820 may be located on the transmissive layer 630, and the third color filter layer 830 may fill the third filter opening 803 described above.

The organic low-refractive index layer 710 may be formed on the color filter layer 800. The organic low-refractive index layer 710 may include an organic material having a refractive index of about 1.2. The organic low-refractive index layer 710 may include a relatively flat upper surface. The inorganic protective layer 720 may be formed on the organic low-refractive index layer 710. The inorganic protective layer 720 may include an inorganic material, such as silicon oxide, silicon nitride, and silicon oxynitride, and may be formed by CVD.

Referring to FIG. 13B, the bank layer 500 may be formed on the inorganic protective layer 720. The bank layer 500 may include the first bank layer 510 and the second bank layer 520 located on the first bank layer 510. A surface of the first bank layer 510 may be lyophilic, and a surface of the second bank layer 520 may be lyophobic.

The bank layer 500 may include the first to third bank openings 501, 502, and 503. When the second substrate 900 and the first substrate 100 are bonded together, the first to third bank openings 501, 502, and 503 of the bank layer 500 may correspond to the first to third light-emitting diodes LED1, LED2, and LED3 located on the first substrate 100, respectively. The first bank opening 501 of the bank layer 500 may correspond to the first pixel opening OP1 of the pixel-defining layer PDL exposing the first pixel electrode 311, the second bank opening 502 may correspond to the second pixel opening OP2 of the pixel-defining layer PDL exposing the second pixel electrode 312, and the third bank opening 503 may correspond to the third pixel opening OP3 of the pixel-defining layer PDL exposing the third pixel electrode 313.

Because the first to third bank openings 501, 502, and 503 are formed on the second substrate 900 by using a photolithography process, such as exposure and development, the area of the surface of the bank layer 500 in the direction toward the first substrate 100 may be greater than an area of the surface in the direction toward the second substrate 900. Accordingly, as shown in FIG. 9B, the bank layer 500 may have a reverse-tapered shape with reference to the second substrate 900.

Referring to FIG. 13C, by using an inkjet printing process, the first ink Ink1 may be sprayed into the first bank opening 501, the second ink Ink2 may be sprayed into the second bank opening 502, and the third ink Ink3 may be sprayed into the third bank opening 503.

The first ink Ink1 may include the material 611 forming the first quantum dot layer 610. In an embodiment, the first ink Ink1 may include a photosensitive monomer, quantum dots, and scattering particles. Here, the quantum dots included in the first ink Ink1 may include a material selected from among Group II-VI semiconductor compounds, Group III-V semiconductor compounds, Group III-VI semiconductor compounds, Group I-III-VI semiconductor compounds, Group IV-VI semiconductor compounds, or any mixture thereof.

The second ink Ink2 may include the material 621 forming the second quantum dot layer 620. In an embodiment, the second ink Ink2 may include a photosensitive monomer, quantum dots, and scattering particles. Here, the quantum dots included in the second ink Ink2 may include InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or any mixture thereof.

The third ink Ink3 may include the material 631 forming the transmissive layer 630. In an embodiment, the third ink Ink3 may include a photosensitive monomer, quantum dots, and scattering particles.

By adjusting a sprayed amount of each of the first ink Ink1, the second ink Ink2, and the third ink Ink3, shapes of upper surfaces of the material 611 forming the first quantum dot layer 610, the material 621 forming the second quantum dot layer 620, and the material 631 forming the transmissive layer 630 may be determined. For example, as shown in FIG. 13C, the material 621 forming the second quantum dot layer 620 may have a concave shape in which a thickness of a central portion is less than a thickness of a peripheral portion. In another embodiment, the material 621 forming the second quantum dot layer 620 may have a convex shape in which the thickness of the central portion is greater than the thickness of the peripheral portion.

Referring to FIG. 13D, a fourth ink Ink4 may be sprayed into the second bank opening 502 by using an inkjet printing process.

The fourth ink Ink4 may include the material 641 forming the first organic capping layer 640. In an embodiment, the photosensitive monomer included in the material 621 forming the second quantum dot layer 620 may be the same material as the material 641 forming the first organic capping layer 640.

The thickness of the material 641 forming the first organic capping layer 640 may be in a range of about 0.1 nm to about 3 nm. In an embodiment, the material 641 forming the first organic capping layer 640 may have a constant thickness, as shown in FIG. 13D. For example, the upper surface 641us of the material 641 forming the first organic capping layer 640 may have a similar shape to the shape of the upper surface 621us of the material 621 forming the second quantum dot layer 620.

In another embodiment, the material 641 forming the first organic capping layer 640 may have a convex shape in which the thickness of the central portion is greater than a thickness of the peripheral portion adjacent to the sidewall of the second bank opening 502.

Although not shown in FIG. 13D, the material forming the second organic capping layer may be applied onto the material 611 forming the first quantum dot layer 610 by spraying the fourth ink Ink4 into the first bank opening 501.

Although not shown in FIG. 13E, an infrared ray may be irradiated to the material 611 forming the first quantum dot layer 610, the material 621 forming the second quantum dot layer 620, the material 631 forming the transmissive layer 630, and the material 641 forming the first organic capping layer 640, so that the first quantum dot layer 610, the second quantum dot layer 620, the transmissive layer 630, and the first organic capping layer 640 may be formed.

The second quantum dot layer 620 and the first organic capping layer 640 may be crosslinked to each other and formed. Until the inorganic capping layer PVL is formed, a decrease in light conversion efficiency by exposure of the second quantum dot layer 620 to light and/or oxygen may be prevented or reduced by the first organic capping layer 640.

Thereafter, by using CVD, the inorganic capping layer PVL may be formed on the bank layer 500 to cover the first quantum dot layer 610, the first organic capping layer 640, and the transmissive layer 630.

Referring to FIG. 13F, the first substrate 100 including the circuit layer 200, the light-emitting diode layer 300, and the encapsulation layer 400 may be bonded to the second substrate 900.

The first substrate 100 and the second substrate 900 may be bonded together such that the color filter layer 800 faces the direction (e.g., a −z direction) to the first substrate 100. In an embodiment, the first to third filter openings 801, 802, and 803 of the color filter layer 800 may correspond to the first to third light-emitting diodes LED1, LED2, and LED3, respectively.

The first substrate 100 and the second substrate 900 may be bonded together outside a display area by a bonding member, such as a sealant. When desirable, a filler (not shown) may fill a space between a stacked body on the first substrate 100 and a stacked body on the second substrate 900.

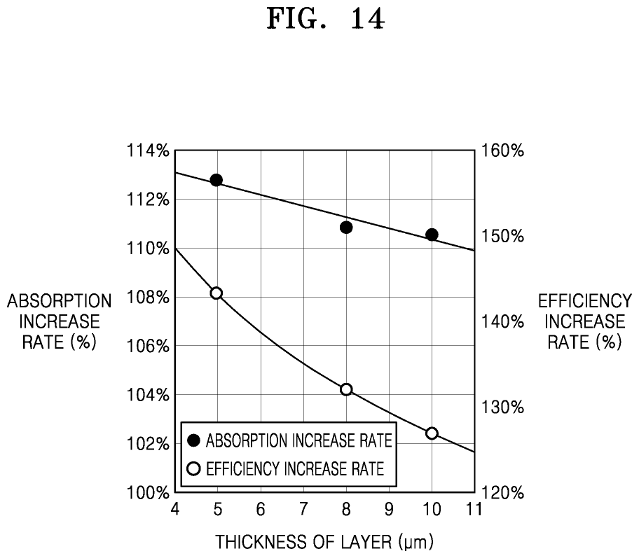

FIG. 14 is a graph showing a light absorption efficiency increase rate and a light conversion efficiency increase rate according to a thickness of a quantum dot layer of a display apparatus according to an embodiment.

The light absorption efficiency increase rate and the light conversion efficiency increase rate may be calculated by comparing light absorption efficiency and light conversion efficiency of a quantum dot layer including AgInₓGa₍₁₋ₓ₎S₂ as a quantum dot, with light absorption efficiency and light conversion efficiency of a quantum dot layer that includes the same components as the quantum dot layer described above, but includes InP as a quantum dot.

As can be identified in FIG. 14, when compared with the quantum dot layer including InP as a quantum dot, the light absorption efficiency of the quantum dot layer including AgInₓGa₍₁₋ₓ₎S₂ as a quantum dot may increase by 110% to 113%, and the light conversion efficiency may increase by 120% to 150%.

When InP is used as a quantum dot, a size of a quantum dot for converting blue light into green light may be about 2 nm. When the size of the quantum dot is less than or equal to about 2 nm, a non-absorption section may occur within a wavelength range of the blue light emitted by a light-emitting diode due to the quantum confinement effect.

On the other hand, Ag InₓGa₍₁₋ₓ₎S₂ has a smaller band gap than In P, and thus, the quantum dot size in which the quantum confinement effect occurs may be relatively large. Accordingly, by reducing the non-absorption section within the wavelength range of the blue light emitted by the light-emitting diode, high light absorption efficiency and light conversion efficiency may be obtained.

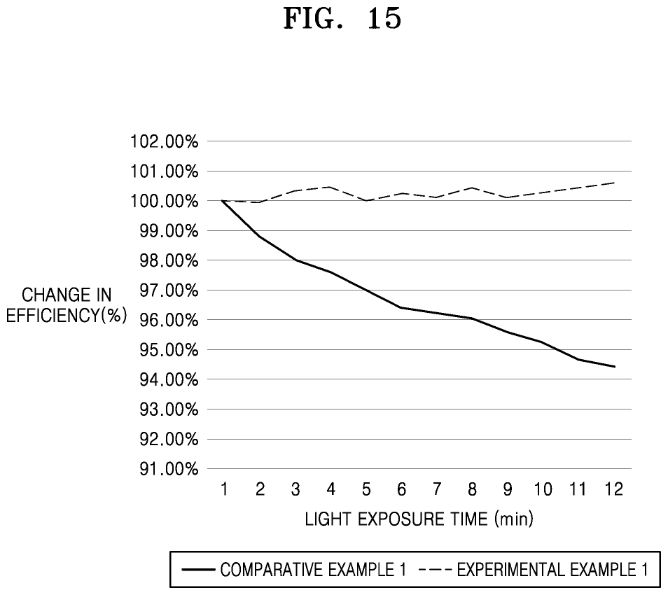

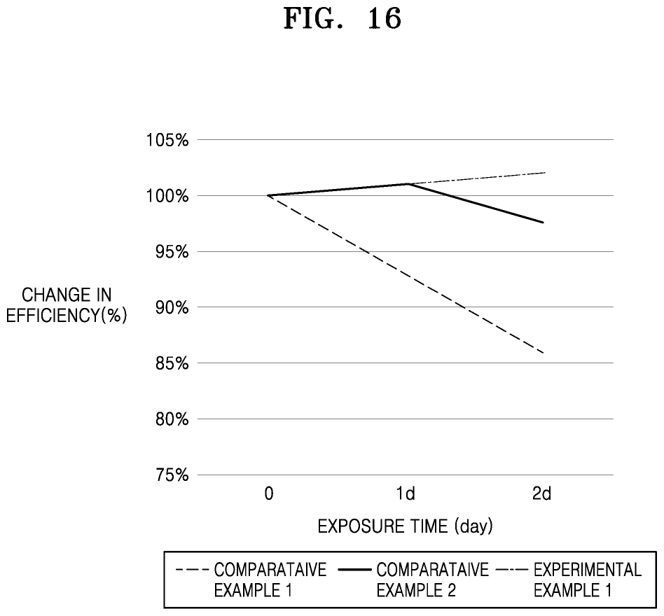

FIG. 15 is a graph showing light conversion efficiency according to a light exposure time of the display apparatus according to an experimental example and a comparative example, and FIG. 16 is a graph showing light conversion efficiency according to a light exposure time of the display apparatus according to an experimental example and comparative examples.

As shown in FIG. 5, the circuit layer 200, the light-emitting diode layer 300, the encapsulation layer 400, and the bank layer 500 are formed on the first substrate 100. By an inkjet process, the first quantum dot layer 610 may be formed in the first bank opening 501 of the bank layer 500, the second quantum dot layer 620 and the first organic capping layer 640 may be formed in the second bank opening 502, and the transmissive layer 630 may be formed in the third bank opening 503. The second quantum dot layer 620 may include AgInₓGa₍₁₋ₓ₎S₂ quantum dots. The inorganic capping layer PVL may be formed on the bank layer 500 to cover the first quantum dot layer 610, the first organic capping layer 640, and the transmissive layer 630. Thereafter, the second substrate 900 is bonded onto the first substrate 100 to manufacture the display apparatus according to Experimental Example 1.

Although the display apparatus according to Comparative Example 1 is manufactured in the same manner as in the display apparatus according to Experimental Example 1, in the display apparatus according to the Comparative Example 1, an inorganic capping layer is formed on a second quantum dot layer instead of a first organic capping layer.

Although the display apparatus according to Comparative Example 2 is manufactured in the same manner as in the display apparatus according to Comparative Example 1, in the display apparatus according to Comparative Example 2, the second quantum dot layer includes InP quantum dots.

FIG. 15 shows light conversion efficiency of the second quantum dot layer when the display apparatuses according to Experimental Example 1 and Comparative Example 1 are exposed to light having a wavelength of about 460 nm under atmospheric conditions before forming the inorganic capping layer PVL.

In Comparative Example 1, it can be seen that the light conversion efficiency continuously decreases as the exposure time increases. This is because AgInₓGa₍₁₋ₓ₎S₂ quantum dots included in the second quantum dot layer are damaged by contact with oxygen or the like under atmospheric conditions. On the other hand, in Experimental Example 1, it can be identified that the light conversion efficiency of 100% or more is maintained even when the exposure time is increased.

FIG. 16 shows light conversion efficiency of the second quantum dot layer when the display apparatuses according to Experimental Example 1, Comparative Example 1, and Comparative Example 2 are exposed to light having a wavelength of 590 nm under atmospheric conditions before forming the inorganic capping layer PVL.

In Comparative Example 1, it can be identified that the light conversion efficiency continuously decreases as the exposure time increases. As described above, AgInₓGa₍₁₋ₓ₎S₂ quantum dots included in the second quantum dot layer are damaged by contact with oxygen or the like under atmospheric conditions.

In Comparative Example 2, when relatively stable InP quantum dots are included, the light conversion efficiency does not decrease until 1 day passes, but it can be identified that the light conversion efficiency decreases after 1 day has passed.

On the other hand, in Experimental Example 1, it can be identified that the light conversion efficiency of 100% or more is maintained even when the exposure time is 2 days. In Experimental Example 1, the first organic capping layer 640 blocks the second quantum dot layer 620 from contacting oxygen or the like, so that a decrease in the light conversion efficiency of the second quantum dot layer 620 during the delay time before the formation of the inorganic capping layer PVL may be prevented or reduced.

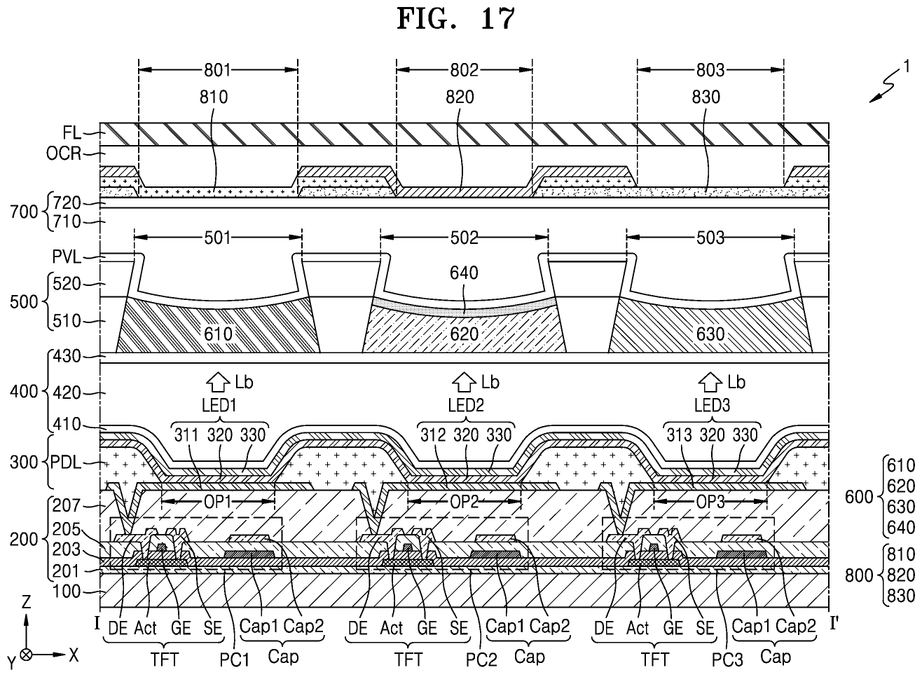

FIG. 17 is a schematic cross-sectional view of a part of the display apparatus according to an embodiment. FIG. 17 differs from FIG. 5, at least in that the low-refractive index layer 700 is formed on the bank layer 500 and the color conversion-transmissive layer 600, and the color filter layer 800 is formed on the low-refractive index layer 700, such that the second substrate is omitted. Hereinafter, descriptions of elements that are same or similar as or to each other may be omitted, and only differences may be described.

Referring to FIG. 17, the bank layer 500 including the first to third bank openings 501, 502, and 503 may be disposed on the encapsulation layer 400. The first to third bank openings 501, 502, and 503 of the bank layer 500 may correspond to the first to third light-emitting diodes LED1, LED2, and LED3, respectively. The first bank opening 501 of the bank layer 500 may correspond to the first pixel opening OP1 of the pixel-defining layer PDL exposing the first pixel electrode 311, the second bank opening 502 may correspond to the second pixel opening OP2 of the pixel-defining layer PDL exposing the second pixel electrode 312, and the third bank opening 503 may correspond to the third pixel opening OP3 of the pixel-defining layer PDL exposing the third pixel electrode 313.

In an embodiment, as shown in FIG. 5, the bank layer 500 may include a first bank layer 510 having a lyophilic surface and a second bank layer 520 having a lyophobic surface. For example, the first bank layer 510 including a lyophilic material may be located on the encapsulation layer 400, and the second bank layer 520 including a lyophobic surface may be located on the first bank layer 510. In another embodiment, the first bank layer 510 and the second bank layer 520 may include a same material as each other, and lyophobic properties may be rendered only to the surface of the second bank layer 520 by using CF₄ plasma treatment or the like.

The blue light Lb generated by the first light-emitting diode LED1 may be converted into the red light Lr by the first quantum dot layer 610 located in the first bank opening 501, and emitted to the outside. The first quantum dot layer 610 described above may overlap the first pixel electrode 311 when viewed from the direction (e.g., a z-axis direction) perpendicular to the first substrate 100. The first quantum dot layer 610 may include a photosensitive polymer, quantum dots, and scattering particles, which have light-transmitting properties.

The blue light Lb generated by the second light-emitting diode LED2 may be converted into the green light Lg by the second quantum dot layer 620 located in the second bank opening 502, and emitted to the outside. The second quantum dot layer 620 described above may overlap the second pixel electrode 312 when viewed from the direction (e.g., a z-axis direction) perpendicular to the first substrate 100. The second quantum dot layer 620 may include a photosensitive polymer, quantum dots, and scattering particles, which have light-transmitting properties.

The quantum dots of the second quantum dot layer 620 may include a material selected from among Group III-V compounds, Group III-VI compounds, Group II-VI compounds, Group I-III-VI compounds, and a mixture thereof. In an embodiment, the second quantum dot layer 620 may include InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or any mixture thereof.

The first organic capping layer 640 may be located on the second quantum dot layer 620 in the second bank opening 502. The first organic capping layer 640 described above may overlap the second pixel electrode 312 when viewed from the direction (e.g., a z-axis direction) perpendicular to the first substrate 100.

The first organic capping layer 640 may be a photosensitive polymer. For example, a monomer for forming the first organic capping layer 640 may be photosensitive acryl-based resin. In an embodiment, the monomer for forming the first organic capping layer 640 may include hexamethylene diacrylate, tetraethylene glycol diacrylate, dipropylene glycol diacrylate, tripropylene glycol diacrylate, or any mixture thereof.

As shown in FIG. 17, the first organic capping layer 640 may have a constant thickness on the upper surface of the second quantum dot layer 620. For example, the upper surface of the first organic capping layer 640 may have a same or similar shape as or to the upper surface of the second quantum dot layer 620. In another embodiment, the second quantum dot layer 620 may have a concave shape, and the first organic capping layer 640 may have a convex shape in which the thickness of the central portion is greater than the thickness of the peripheral portion adjacent to the second bank opening 502.

A fixed point at which the upper surface of the first organic capping layer 640 contacts the sidewall of the second bank opening 502 may coincide with or be adjacent to a point at which the interface between the first bank layer 510 and the second bank layer 520 contacts the sidewall of the second bank opening 502. For example, the fixed point may coincide with or be located adjacent to a point at which a surface of the sidewall of the second bank opening 502 changes from lyophilic to lyophobic.

The first organic capping layer 640 may prevent or reduce reduction in light conversion efficiency due to exposure of the second quantum dot layer 620 to light and/or oxygen before an inorganic capping layer PVL is formed.

The blue light Lb generated in the third light-emitting diode LED3 may be emitted to the outside without wavelength conversion. In an embodiment, the transmissive layer 630 may be located in the third bank opening 503 of the bank layer 500 overlapping the third pixel electrode 313. The transmissive layer 630 may overlap the third pixel electrode 313 when viewed from the direction (e.g., a z-axis direction) perpendicular to the first substrate 100. The transmissive layer 630 may include a photosensitive polymer having light transmittance and scattering particles.

The inorganic capping layer PVL may be located on the bank layer 500 to cover the first quantum dot layer 610, the first organic capping layer 640, and the transmissive layer 630. The inorganic capping layer PVL may include an inorganic insulating material, such as silicon oxide, silicon nitride, and/or silicon oxynitride.

The low-refractive index layer 700 may be located on the inorganic capping layer PVL. The low-refractive index layer 700 may include the organic low-refractive index layer 710 and the inorganic protective layer 720. The organic low-refractive index layer 710 may have a refractive index of about 1.2. The organic low-refractive index layer 710 may be applied onto the bank layer 500 and the color conversion-transmissive layer 600 so as to provide a flat base surface to elements located over the organic low-refractive index layer 710. Scattered light passing through the color conversion-transmissive layer 600 may be totally reflected at an interface of the organic low-refractive index layer 710 and re-scattered within the color conversion-transmissive layer 600. The inorganic protective layer 720 may be formed on the organic low-refractive index layer 710. The inorganic protective layer 720 may include an inorganic material, such as silicon oxide, silicon nitride, and silicon oxynitride, and may be formed by CVD.

The color filter layer 800 may be located on the inorganic protective layer 720. After the inorganic protective layer 720 is formed, the color filter layer 800 may be formed through a continuous process on a base surface on which the inorganic protective layer 720 is provided.

The color filter layer 800 may include the first to third filter openings 801, 802, and 803. The first to third filter openings 801, 802, and 803 of the color filter layer 800 may correspond to the first to third light-emitting diodes LED1, LED2, and LED3, respectively.

The color filter layer 800 may include the first color filter layer 810 transmitting only light of a wavelength in a range of about 625 nm to about 780 nm, the second color filter layer 820 transmitting only light of a wavelength in a range of about 495 nm to about 570 nm, and the third color filter layer 830 transmitting only light of a wavelength in a range of about 450 nm to about 495 nm.

The third color filter layer 830 may be located on the inorganic protective layer 720, the first color filter layer 810 may be located on the third color filter layer 830, and the second color filter layer 820 may be located on the first color filter layer 810. At least two layers from among the first color filter layer 810, the second color filter layer 820, and the third color filter layer 830 may overlap each other in an area between the first to third filter openings 801, 802, and 803. An area in which the at least two layers from among the first color filter layer 810, the second color filter layer 820, and the third color filter layer 830 may serve as a black matrix.

Because the color filter layer 800 is formed (e.g., directly formed) on a base surface provided by the inorganic protective layer 720, the first color filter layer 810, the second color filter layer 820, and the third color filter layer 830 may contact (e.g., directly contact) the inorganic protective layer 720.

A film layer FL may be located on the color filter layer 800. The film layer FL may be bonded onto the color filter layer 800 through an adhesive layer, such as an optically clear adhesive or optically clear resin (OCR).

In some embodiments, the film layer FL may be provided as an anti-reflection film. The film layer FL may be provided as a polarization film. The polarization film may include a linear planarization plate and a phase delay film, such as a quarter-wave (λ/4) plate.

In the display apparatus 1 described with reference to FIG. 17, because the color filter layer 800 is formed (e.g., directly formed) on the inorganic protective layer 720, a second substrate for forming the color filter layer 800 may be omitted. Accordingly, a process of bonding the first substrate 100 and the second substrate together may be omitted, and thus, a manufacturing process may be simplified and a thickness of the display apparatus 1 may be reduced.

According to an embodiment configured as described above, a display apparatus on which a high-quality image may be displayed may be implemented. However, the scope of the disclosure is not limited by this effect.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display apparatus comprising:
a first substrate;
a first light-emitting diode, a second light-emitting diode, and a third light-emitting diode, which are disposed on the first substrate and emit light of a wavelength belonging to a first wavelength band;
an encapsulation layer covering the first light-emitting diode, the second light-emitting diode and the third light-emitting diode;
a bank layer on the encapsulation layer, the bank layer comprising:
a first bank opening corresponding to the first light-emitting diode;
a second bank opening corresponding to the second light-emitting diode; and
a third bank opening corresponding to the third light-emitting diode;
a first quantum dot layer disposed in the first bank opening and which converts light of a wavelength belonging to the first wavelength band to light of a wavelength belonging to a second wavelength band;
a second quantum dot layer disposed in the second bank opening and which converts light of a wavelength belonging to the first wavelength band to light of a wavelength belonging to a third wavelength band;
a first organic capping layer disposed in the second bank opening and covering the second quantum dot layer; and
an inorganic capping layer covering the bank layer, the first quantum dot layer, and the first organic capping layer.

2. The display apparatus of claim 1, wherein the bank layer further comprises:
a first bank layer on the encapsulation layer and having a lyophilic surface; and
a second bank layer on the first bank layer and having a lyophobic surface.

3. The display apparatus of claim 2, wherein a fixed point at which an upper surface of the first organic capping layer contacts a sidewall of the second bank opening coincides with or is adjacent to a point at which an interface between the first bank layer and the second bank layer contacts the sidewall of the second bank opening.

4. The display apparatus of claim 1, wherein the second quantum dot layer has a concave shape in which a thickness of a central portion is less than a thickness of a peripheral portion adjacent to a sidewall of the second bank opening.

5. The display apparatus of claim 4, wherein, in the first organic capping layer, a thickness of a central portion is equal to a thickness of a peripheral portion adjacent to the sidewall of the second bank opening.

6. The display apparatus of claim 4, wherein the first organic capping layer has a convex shape in which a thickness of a central portion is greater than a thickness of a peripheral portion adjacent to the sidewall of the second bank opening.

7. The display apparatus of claim 1, wherein
the second quantum dot layer has a convex shape in which a thickness of a central portion is greater than a thickness of a peripheral portion adjacent to a sidewall of the second bank opening, and
in the first organic capping layer, a thickness of a central portion is equal to a thickness of a peripheral portion.

8. The display apparatus of claim 1, wherein a thickness of the first organic capping layer is in a range of about 0.1 μm to about 3 μm.

9. The display apparatus of claim 1, wherein the second quantum dot layer comprises InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or a mixture thereof.

10. The display apparatus of claim 9, wherein
the first wavelength band is in a range of about 450 nm to about 495 nm, and
the third wavelength band is in a range of about 495 nm to about 570 nm.

11. The display apparatus of claim 1, further comprising:
a second organic capping layer disposed in the first bank opening and covering the first quantum dot layer.

12. The display apparatus of claim 1, further comprising:
a second substrate over the first substrate with the bank layer therebetween; and
a color filter layer disposed on a lower surface of the second substrate in a direction toward the first substrate, wherein
the color filter layer comprises a first filter opening, a second filter opening, and a third filter opening which respectively overlap the first light-emitting diode, the second light-emitting diode, and the third light-emitting diode, when viewed from a direction perpendicular to the first substrate.

13. The display apparatus of claim 12, further comprising:
a low-refractive index layer contacting a lower surface of the color filter layer in the direction toward the first substrate.

14. The display apparatus of claim 13, further comprising:
a filler between the inorganic capping layer and the low-refractive index layer.

15. A display apparatus comprising:
a second substrate;
a color filter layer on the second substrate, and comprising a first filter opening, a second filter opening, and a third filter opening;
a low-refractive index layer on the color filter layer;
a bank layer on the low-refractive index layer, the bank layer comprising:
a first bank opening corresponding to the first filter opening;
a second bank opening corresponding to the second filter opening; and
a third bank opening corresponding to the third filter opening;
a first quantum dot layer disposed in the first bank opening and which converts light of a wavelength belonging to a first wavelength band into light of a wavelength belonging to a second wavelength band;
a second quantum dot layer disposed in the second bank opening and which converts light of a wavelength belonging to the first wavelength band to light of a wavelength belonging to a third wavelength band;
a first organic capping layer disposed in the second bank opening and covering the second quantum dot layer; and
an inorganic capping layer covering the bank layer, the first quantum dot layer, and the first organic capping layer.

16. The display apparatus of claim 15, wherein the bank layer further comprises:
a first bank layer on the low-refractive index layer and having a lyophilic surface; and
a second bank layer on the first bank layer and having a lyophobic surface.

17. The display apparatus of claim 16, wherein a fixed point at which an upper surface of the first organic capping layer contacts a sidewall of the second bank opening coincides with or is adjacent to a point at which an interface between the first bank layer and the second bank layer contacts the sidewall of the second bank opening.

18. The display apparatus of claim 15, wherein the second quantum dot layer has a concave shape in which a thickness of a central portion is less than a thickness of a peripheral portion adjacent to a sidewall of the second bank opening.

19. The display apparatus of claim 18, wherein, in the first organic capping layer, a thickness of a central portion is equal to a thickness of a peripheral portion adjacent to the sidewall of the second bank opening.

20. The display apparatus of claim 18, wherein the first organic capping layer has a convex shape in which a thickness of a central portion is greater than a thickness of a peripheral portion adjacent to the sidewall of the second bank opening.

21. The display apparatus of claim 15, wherein
the second quantum dot layer has a convex shape in which a thickness of a central portion is greater than a thickness of a peripheral portion adjacent to a sidewall of the second bank opening, and
in the first organic capping layer, a thickness of a central portion is equal to a thickness of a peripheral portion.

22. The display apparatus of claim 15, further comprising:
a second organic capping layer disposed in the first bank opening and covering the first quantum dot layer.

23. The display apparatus of claim 15, wherein the second quantum dot layer comprises InₓGa₍₁₋ₓ₎P, AgInₓGa₍₁₋ₓ₎S₂, AgInS₂, AgGaS₂, CuInS₂, CuInSe₂, CuGaS₂, CuGaSe₂, ZnSe, ZnTeₓSe₍₁₋ₓ₎, or a mixture thereof.

24. The display apparatus of claim 15, further comprising:
a first substrate under the second substrate with the bank layer therebetween;
a first light-emitting diode, a second light-emitting diode, and a third light-emitting diode, which are disposed on the first substrate and emit light of a wavelength belonging to the first wavelength band; and
an encapsulation layer covering the first light-emitting diode, the second light-emitting diode and the third light-emitting diode.

25. The display apparatus of claim 24, further comprising:
a filler between the encapsulation layer and the inorganic capping layer.

26. A display apparatus comprising:
a first substrate;
a first light-emitting diode, a second light-emitting diode, and a third light-emitting diode, which are disposed on the first substrate and emit light of a wavelength belonging to a first wavelength band;
an encapsulation layer covering the first light-emitting diode, the second light-emitting diode, and the third light-emitting diode;
a bank layer on the encapsulation layer, the bank layer comprising:
a first bank opening corresponding to the first light-emitting diode;
a second bank opening corresponding to the second light-emitting diode; and
a third bank opening corresponding to the third light-emitting diode;
a first quantum dot layer disposed in the first bank opening and which converts light of a wavelength belonging to the first wavelength band to light of a wavelength belonging to a second wavelength band;
a second quantum dot layer disposed in the second bank opening and which converts light of a wavelength belonging to the first wavelength band to light of a wavelength belonging to a third wavelength band;
a first organic capping layer disposed in the second bank opening and covering the second quantum dot layer;
an inorganic capping layer covering the bank layer, the first quantum dot layer, and the first organic capping layer;
an organic low-refractive index layer on the inorganic capping layer and filling the first bank opening, the second bank opening, and the third bank opening;
an inorganic protective layer on the inorganic low-refractive index layer; and
a color filter layer directly contacting the inorganic protective layer, wherein
the color filter layer comprises a first filter opening, a second filter opening, and a third filter opening which respectively overlap the first light-emitting diode, the second light-emitting diode, and the third light-emitting diode, when viewed from a direction perpendicular to the first substrate.
